(19) United States
(12) Patent Application Publication
(10) Pub. No.: US 2026/0237425 A1
(43) Pub. Date: Aug. 13, 2026

(54) MEMORY DEVICE USING MIRROR CELLS FOR ARTIFICIAL INTELLIGENCE PROCESSING

(71) Applicant: Micron Technology, Inc., Boise, ID (US)

(72) Inventors: Hernan Castro, Shingle Springs, CA (US); Kamal Karda, Boise, ID (US)

(21) Appl. No.: 19/422,289

(22) Filed: Dec. 16, 2025

Related U.S. Application Data
(60) Provisional application No. 63/755,947, filed on Feb. 7, 2025.

(51) Int. Cl. G11C 11/4096; G06F 7/544; G11C 11/408

(52) U.S. Cl. CPC G11C 11/4096; G06F 7/5443; G11C 11/4085

(57) ABSTRACT

Systems, methods, and apparatus for DRAM devices that perform computations for artificial intelligence models. In one approach, a DRAM device stores weights in target memory cells. The DRAM device includes mirror cells that store an identical state of charge stored by corresponding ones of the target memory cells. During a matrix vector multiplication operation, a controller accumulates charge stored in the target memory cells. The accumulated charge is used to provide a result. After accumulating the charge to provide the result, the controller restores the target memory cells to their original state based on the charge stored in the corresponding one of the mirror cells.

### RELATED APPLICATIONS

The present application claims priority to Prov. U.S. Pat. App. Ser. No. 63/755,947 filed Feb. 7, 2025, the entire disclosure of which application is hereby incorporated herein by reference.

### FIELD OF THE TECHNOLOGY

At least some embodiments disclosed herein relate to memory devices in general and more particularly, but not limited to, memory devices that use memory cells for performing multiplication and other operations.

### BACKGROUND

Limited memory bandwidth is a significant problem in machine learning systems. For example, DRAM devices used in current systems store large amounts of weights and activations used in deep neural networks (DNNs).

In one example, deep learning machines, such as those supporting processing for convolutional neural networks (CNNs), perform processing to determine a huge number of calculations per second. For example, input/output data, deep learning network training parameters, and intermediate results are constantly fetched from and stored in one or more memory devices (e.g., DRAM). A DRAM type of memory is typically used due to its cost advantages when large storage densities are involved (e.g., storage densities greater than 100 MB). In one example of a deep learning hardware system, a computational unit (e.g., a system-on-chip (SOC), FPGA, CPU, or GPU) is attached to a memory device(s) (e.g., a DRAM device).

Existing computer architectures use processor chips specialized for serial processing and DRAMs optimized for high density memory. The interface between these two devices is a major bottleneck that introduces latency and bandwidth limitations and adds a considerable overhead in power consumption. Memory on-chip is area expensive and it is not possible to add large amounts of memory to the CPU and GPU processors currently used to train and deploy DNNs.

Memory in neural networks is used to store input data, weight parameters and activations as an input propagates through the network. In training, activations from a forward pass must be retained until they can be used to calculate the error gradients in the backwards pass. As an example, a network can have 26 million weight parameters and compute 16 million activations in a forward pass. If a 32-bit floating-point value is used to store each weight and activation, this corresponds to a total storage requirement of 168 MB.

GPUs and other machines need significant memory for the weights and activations of a neural network. GPUs cannot efficiently execute directly the small convolutions used in deep neural networks, so they need significant activation or weight storage. Finally, memory is also required to store input data, temporary values and program instructions. For example, a high-performance GPU may need over 7 GB of local DRAM.

Large amounts of storage data cannot be kept on the GPU processor. In many cases, high performance GPU processors may have only 1 KB of memory associated with each of the processor cores that can be read fast enough to saturate the floating-point data path. Thus, at each layer of a DNN, the GPU needs to save the state to external DRAM, load up the next layer of the network, and then reload the data. As a result, the off-chip memory interface suffers the burden of constantly reloading weights and saving and retrieving activations. This significantly slows down training time and increases power consumption.

In one example, images and other sensors are used and generate large amounts of data. It is inefficient to transmit certain types of data from the sensors to general-purpose microprocessors (e.g., central processing units (CPU)) for processing in some applications. For example, it is inefficient to transmit image data from image sensors to microprocessors for image segmentation, object recognition, feature extraction, etc.

Some image processing can include intensive computations involving multiplications of columns or matrices of elements for accumulation. Some specialized circuits have been developed for the acceleration of multiplication and accumulation operations. For example, a multiplier-accumulator (MAC unit) can be implemented using a set of parallel computing logic circuits to achieve a computation performance higher than general-purpose microprocessors.

### BRIEF DESCRIPTION OF THE DRAWINGS

The embodiments are illustrated by way of example and not limitation in the figures of the accompanying drawings in which references indicate similar elements.

FIG. 1 shows an integrated circuit device having sensors, a memory cell array, and circuits to perform inference computations according to one embodiment.

FIG. 2 shows the computation of a column of weight bits multiplied by a column of input bits to provide an accumulation result according to one embodiment.

FIG. 3 shows a method of computation in an integrated circuit device based on summing output currents from memory cells according to one embodiment.

FIG. 4 shows an analog weight-stationary architecture for matrix vector multiplication (MVM) according to one embodiment.

FIG. 5 shows sensing circuitry coupled to a bitline used to access NAND flash memory cells according to one embodiment.

FIG. 6 shows an architecture having resistive random access memory (RRAM) or NOR memory cells arranged in a parallel configuration for performing multiplication according to one embodiment.

FIG. 7 shows a memory device having integrated circuit dies that are bonded together for performing multiplication according to one embodiment.

FIG. 8 shows a memory device storing data in one or more memory arrays for a host device according to one embodiment.

FIG. 9 shows sense amplifier latches to hold data associated with memory cells of a memory array according to one embodiment.

FIG. 10 shows a sensing line used to accumulate charge from memory cells according to one embodiment.

FIG. 11 shows tiles in a memory array used to store weights to perform multiplication of an input vector by the weights according to one embodiment.

FIG. 12 shows sensing circuitry for determining a state of one or more memory cells according to one embodiment.

FIG. 13 shows exemplary voltage waveforms for inputs to the sensing circuitry of FIG. 12.

FIG. 14 shows exemplary voltage waveforms for wordlines and a digit line in a memory array having memory cells being sensed using the sensing circuitry of FIG. 12.

FIG. 15 shows an input stream for multiplication by weights stored in a memory array where the input stream is provided to the memory array in sequential time slices according to one embodiment.

FIG. 16 shows replicating of weights stored in a memory array so that an input stream can be split into two parallel bit streams according to one embodiment.

FIG. 17 shows an example of the calculation of partial products for the multiplication of an input by stored weights according to one embodiment.

FIGS. 18A-18B show an example of the summation of partial products for each of multiple digit lines according to one embodiment.

FIGS. 19-20 show summation of results from multiple low-resolution analog-to-digital converters (ADCs) to provide a final result that is equivalent to a high-resolution ADC according to one embodiment.

FIG. 21 shows an example of a logical tile distributed across multiple physical tiles.

FIG. 22 shows exemplary timing for multiplications performed for the logical tile of FIG. 21 using an input stream provided in time slices with each time slice followed by multiple writeback cycles.

FIG. 23 shows a method for providing a digital result based on accumulating charge from multiple memory cells according to one embodiment.

### DETAILED DESCRIPTION

The following disclosure describes various embodiments for memory devices that use memory cells (e.g., multi-pillar memory cells, memory cells based on a destructive read technology such as in a DRAM device) to perform multiplication and other operations. Each memory cell provides an output current or charge depending on its prior programming and the input to the memory cell during read inference. The output currents or charges are accumulated on a sensing line (e.g., a digit line).

In one embodiment, the memory devices apply biases to access lines (e.g., wordlines and/or bitlines) when performing multiplication and/or other operations using a three-dimensional NAND flash or dynamic random access memory (DRAM) cell array. The memory device may, for example, store data used by a host device (e.g., a computing device of an autonomous vehicle, or another computing device that accesses data stored in the memory device). In one example, the memory device is a solid-state drive mounted in an electric vehicle.

In the case of memory devices based on accumulating output currents from memory cells, there can be a combination of various mechanisms that can cause a change in the magnitude of the output current from a memory cell so that it is higher or lower than the desired initial target threshold voltage or current to which the memory cell has been programmed. For example, for an MVM or other operation based on a sum of output currents from selected memory cells, any cell/array mechanism that results in a deviation from the intended target current values for the cells can result in an error.

One problem that can cause such an error is IR voltage drop (or simply IR drop) along access lines that results from the output current flows in a memory array. This problem can be particularly acute for currents in bitlines that are used to accumulate output currents from strings of memory cells during MVM. For example, bitlines (BL) accumulate current for an MVM function of a memory device. The voltage on each bitline varies due to IR drops. The IR drops can be a function of bitline resistance, the weight range (e.g., range of target output currents) used to program memory cells, and/or weight and input distribution (e.g., input patterns) during inference reads. The IR drop reduces the target voltage across each string, which introduces error in the MVM function.

The IR drop can be, for example, a function of memory cell location within an array tile, and/or current in the array. The current is a function of both the input to the multiplication and the weight pattern of the memory cells. In one example, one factor that affects IR drop is the location of a memory cell relative to one or more voltage drivers. Bitlines and pillars have some resistance, so the IR drop seen by a cell increases as the cell is located further from the driver(s).

To counter such IR drops, various embodiments described below reduce the effective resistance of the bitlines. By reducing effective IR drops along the bitlines, the window budget can be improved and/or error in the MVM reduced. This window budget is sometimes expressed as an acceptable amount of error. The extent of error that can be tolerated also depends, for example, on the AI model being used.

In one example, a bitline is formed using the top metal for a NAND memory cell array. Output currents from memory cells are accumulated by the bitline for multiplication. Sometimes the accumulated current can be significant if, for example, numerous strings along a bitline are conducting high currents due to the programmed state of memory cells and/or active inputs. This can cause large IR drops and create errors in the multiplication results.

In one embodiment, a memory cell array uses multi-pillar memory cells to reduce IR drops when performing computations for layers of a neural network. For example, these computations include matrix vector multiplication (MVM) for each layer of the neural network. The weights for the neural network are stored in the memory cell array and multiplication using the weights is performed in the memory cell array itself based on output currents from memory cells in the array. The output currents are digitized and used by a controller to support the MVM.

In addition to the above, improved power efficiency is particularly desirable for use of neural networks on mobile devices and automobiles. Storing the weights for a neural network in the memory device and doing the multiplication in the memory device avoids or reduces the need to move the weights to a central processing unit or other processing device. This reduces the power consumption required to move data to and from memory, and also reduces the memory bandwidth problem described herein.

More generally, neural networks are one of the most popular classes of machine learning algorithms (e.g., modeled after our understanding of how the brain works). For example, a network has a large number of neurons that on their own perform fairly simple computations, but together can learn complex and non-linear functions. For example, neuron computation is basically multiplication of multiple input values by neuron weights (which represent how important each input is to the computation), and summing of the results. The weights are learned during network training. Each result is then passed through a non-linear activation function to allow the neuron to learn complex relationships.

In terms of computational burden, the multiplication of all input values by neuron weights for all neurons in the network is the most demanding use of processing power. For example, this multiplication can be 90% or more of the computational requirement, depending on the network design. When scaled to a full layer of the neural network, the computation is vectorized and becomes a matrix vector multiplication problem. The computations are also sometimes referred to as dot product or sum-of-products (SOP) computations.

Deep learning technologies are an exemplary implementation of neural networks and have been playing a significant role in a variety of applications such as image classification, object detection, speech recognition, natural language processing, recommender systems, automatic generation, and robotics etc. Many domain-specific deep learning accelerators (DLA) (e.g., GPU, TPU and embedded NPU), have been introduced to provide the required efficient implementations of deep neural networks (DNN) from cloud to edge. However, the limited memory bandwidth is still a critical challenge due to frequent data movement back and forth between compute units and memory in deep learning, especially for energy constrained systems and applications (e.g., edge AIs).

Conventional Von-Neumann computer architecture has developed with processor chips specialized for serial processing and DRAMs optimized for high density memory. The interface between these two devices is a major bottleneck that introduces latency and bandwidth limitations and adds a considerable overhead in power consumption. With the growing demand of higher accuracy and higher speed for AI applications, larger DNN models are developed and implemented with huge amounts of weights and activations. The resulting bottlenecks of memory bandwidth and power consumption on inter-chip data movement are significant technical problems.

Over time, neural networks continue to grow exponentially in complexity, which means there are many more computations required. This stresses the performance of traditional computation architectures. For example, purpose-built compute blocks are needed for the MVM operation to meet performance requirements (GPUs, Digital Accelerators). Also, neuron weights must be fetched from memory, which both causes performance bottlenecks, and is energy inefficient, as mentioned above.

In some cases, the precision of the computations can be reduced to address these concerns. For example, the selection of the type of neural network training can enable roughly equivalent neural network accuracy with significantly lower precision. The lower precision can improve the performance and/or energy efficiency of a neural network implementation. Also, the use of a lower precision can be supportive of storing weights in memory and performing multiplication in the memory, as described herein.

For example, when using lower precision representations of weights and inputs (e.g., using a smaller number of bits for each weight or input), a key aspect to consider is the final answer such as a classification of an image. In many cases, the accuracy in obtaining the correct final answer can be maintained almost the same (e.g., only 2-5% decrease) even when using lower precision if the neural network model is structured properly (e.g., the manner or approach used to train the network). For example, analog multiplication in the memory itself may be even more desirable because of the ability to achieve similar accuracy as in traditional approaches, but with this lower precision.

A neural network design itself typically dictates the size of the MVM operation at every layer of the network. Each layer can have a different number of features and neurons. In one embodiment, the MVM computation will take place in a portion of a NAND flash, DRAM, or other memory array. This portion is represented in the array as tiles.

In one embodiment, a memory device has memory cells configured in an array, with each memory cell programmed, for example, to allow an amount of current to go through when a voltage is applied in a predetermined voltage region to represent a first logic state (e.g., a first value stored in the memory cell), or a negligible amount of current to represent a second logic state (e.g., a second value stored in the memory cell).

The memory device performs computations based on applying voltages in a digital fashion, in the form of whether or not to apply an input voltage to generate currents for summation over a line (e.g., a bitline of a memory array). The total current on the line will be the multiple of the amount of current allowed for cells programmed at the first value. In one example, an analog-to-digital converter is used to convert the current to a digital result of a sum of bit-by-bit multiplications.

As mentioned above, memory cells store weights used in multiplication. The weight is set at a target threshold voltage (VT) to sink a specific amount of current (e.g., a target current magnitude that corresponds to the value of the stored weight). The accuracy of this current needs to be maintained to obtain a proper summed value or result from the multiplication. Thus, the accuracy of the MVM computation depends on stable output currents from the memory cells. It is desired that the output current value is consistent across the numerous varying conditions experienced during the operation of a memory device. For example, reducing IR drops by using multi-pillar memory cells can improve this output current consistency.

To address the above IR drop, power efficiency, and/or other technical problems, a memory device integrates memory and processing. In one example, memory and inference computation processing are integrated in the same integrated circuit device. In some embodiments, the memory device is an integrated circuit device having an image or other sensor, a memory cell array, and one or more circuits to use the memory cell array to perform inference computation on data from the sensor. In some embodiments, the memory device includes or is used with various types of sensors (e.g., LIDAR, radar, sound).

Existing methods of matrix vector multiplication use digital logic gates. Digital logic implementations are more complex, consume more silicon area, and dissipate more power as compared to various embodiments described below. These embodiments effectively reduce the multiplication to a memory access function which can be parallelized in an array. The accumulation function is carried out by wires that connect these memory elements, which can also be parallelized in an array. By combining these two features in an array, matrix vector multiplication can be performed more efficiently than methods using digital logic gates.

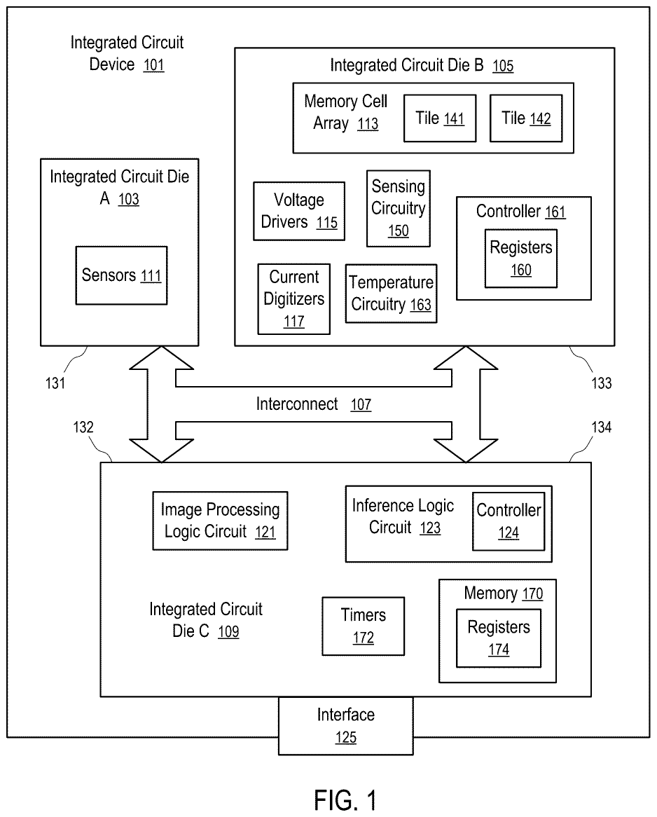

In one embodiment, a NAND analog weight-stationary device is used to perform multiplication. A wordline voltage is applied to gates of memory cells forming one or more synapses of a neural network. In one embodiment, an integrated circuit (IC) device (e.g., 101 of FIG. 1 below) includes a host interface configured to communicate with a host. The IC device includes a memory cell array having memory cells to store weights for a neural network. Access lines (e.g., wordline, bitline) are used to access the memory cells. The IC device also includes logic circuitry to receive, via the host interface from the host, weights for the neural network. The logic circuitry programs a portion of the memory cells of the memory cell array to store the weights.

In one embodiment, an image sensor is configured with an analog capability to support inference computations by using matrix vector multiplication, such as computations of an artificial neural network. The image sensor can be implemented as an integrated circuit device having an image sensor chip and a memory chip. The memory chip can have a 3D memory array configured to support multiplication and accumulation operations. The integrated circuit device includes one or more logic circuits configured to process images from the image sensor chip, and to operate the memory cells in the memory chip to perform multiplications and accumulation operations.

The memory chip can have multiple layers of memory cells. Each memory cell can be programmed to store a bit of a binary representation of an integer weight. Each input line can be applied a voltage according to a bit of an integer. Columns of memory cells can be used to store bits of a weight matrix; and a set of input lines can be used to control voltage drivers to apply read voltages on rows of memory cells according to bits of an input vector.

In one embodiment, the threshold voltage or state of a memory cell used for multiplication and accumulation operations can be programmed such that the current going through the memory cell subjected to a predetermined read voltage is either a predetermined amount representing a value of one stored in the memory cell, or negligible to represent a value of zero stored in the memory cell. When the predetermined read voltage is not applied, the current going through the memory cell is negligible regardless of the value stored in the memory cell. As a result of the configuration, the current going through the memory cell corresponds to the result of a 1-bit weight, as stored in the memory cell, multiplied by a 1-bit input, corresponding to the presence or the absence of the predetermined read voltage driven by a voltage driver controlled by the 1-bit input.

Output currents of the memory cells, representing the results of a column of 1-bit weights stored in the memory cells and multiplied by a column of 1-bit inputs respectively, are connected to a common line (also sometimes referred to as a sensing line herein) for summation. The summed current in the common line is a multiple of the predetermined amount; and the multiples can be digitized and determined using an analog to digital converter or other digitizer. Such results of 1-bit to 1-bit multiplications and accumulations can be performed for different significant bits of weights and different significant bits of inputs. The results for different significant bits can be shifted (e.g., left shifted) to apply the weights of the respective significant bits for summation to obtain the results of multiplications of multi-bit weights and multi-bit inputs with accumulation.

Using the capability of performing multiplication and accumulation operations implemented via memory cell arrays, a logic circuit can be configured to perform inference computations, such as the computation of an artificial neural network.

Various embodiments of memory devices performing multiplication using logical states of memory cells are described below. The memory cells in an array may generally be of various types. Examples include NAND or NOR flash memory cells, DRAM memory cells, and phase-change memory (PCM) cells. In one example, the PCM cells are chalcogenide memory cells. In one example, floating gate or charge trap memory devices in NAND or NOR memory configurations are used.

Summation of results represented by output currents from memory cells can be implemented via connecting the currents to a common line (e.g., a sensing line such as a bitline). The summation of results can be digitized to provide a digital output. In one example, an analog-to-digital converter is used to measure the sum as the multiple of the predetermined amount of current and to provide a digital output.

In one embodiment, a memory device implements unsigned 1-bit to multi-bit multiplication. A multi-bit weight can be implemented via multiple memory cells. Each of the memory cells is configured to store one of the bits of the multi-bit weight, as just described above. A voltage represented by a 1-bit input can be applied to the multiple memory cells separately to obtain results of unsigned 1-bit to 1-bit multiplication as described above.

Each memory cell has a position corresponding to its stored bit in the binary representation of the multi-bit weight. Its digitized output (e.g., from the summing of output currents from memory cells on a common bitline) can be shifted left according to its position in the binary representation to obtain a shifted result. For example, the digitized output of the memory cell storing the least significant bit of the multi-bit weight is shifted by 0 bit; the digitized output of the memory cell storing the second least significant bit of the multi-bit weight is shifted by 1 bit; the digitized output of the memory cell storing the third least significant bit of the multi-bit weight is shifted by 2 bit; etc. The shifted results can be summed to obtain the result of the 1-bit input multiplied by the multi-bit weight stored in the multiple memory cells.

FIG. 1 shows an integrated circuit device 101 having one or more sensors 111, a memory cell array 113, and circuits to perform inference computations according to one embodiment. In FIG. 1, the integrated circuit device 101 has an integrated circuit die 109 having logic circuits 121 and 123, an integrated circuit die 103 having the sensors 111 (e.g., an image sensing pixel array), and an integrated circuit die 105 having the memory cell array 113.

In one example, the integrated circuit die 109 having logic circuits 121 and 123 is a logic chip; the integrated circuit die 103 having the sensors 111 is a sensor chip; and the integrated circuit die 105 having the memory cell array 113 is a memory chip.

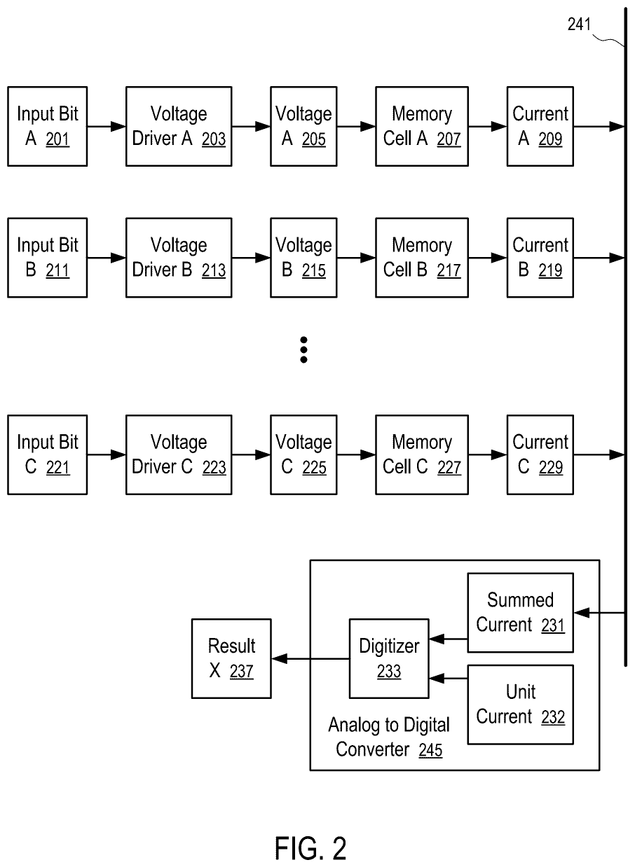

In FIG. 1, the integrated circuit die 105 having the memory cell array 113 further includes voltage drivers 115 and current digitizers 117. The memory cell array 113 is connected such that currents generated by the memory cells in response to voltages applied by the voltage drivers 115 are summed in the array 113 for columns of memory cells (e.g., as illustrated in FIG. 2); and the summed currents are digitized to generate the sum of bit-wise multiplications. The inference logic circuit 123 can be configured to instruct the voltage drivers 115 to apply read voltages according to a column of inputs, and perform shifts and summations to generate the results of a column or matrix of weights multiplied by the column of inputs with accumulation.

In one embodiment, sensing circuitry 150 is coupled to memory cells in tiles 141, 142. Sensing circuitry 150 is used to sense one or more characteristics of the memory cells. In one embodiment, sensing circuitry 150 includes circuitry to precharge bitlines of tiles 141, 142. Sensing circuitry 150 is configured to receive signals from controller 124 and/or read registers 160 to configure sensing operation. In one embodiment, sensing circuitry 150 includes ADCs or other digitizers to convert sums of output currents (or charges in the case of DRAM) from memory cells that are accumulated on access lines (e.g., accumulated on bitlines) to provide digital results (e.g., accumulation results).

The inference logic circuit 123 can be further configured to perform inference computations according to weights stored in the memory cell array 113 (e.g., the computation of an artificial neural network) and inputs derived from the data generated by the sensors 111. Optionally, the inference logic circuit 123 can include a programmable processor that can execute a set of instructions to control the inference computation. Alternatively, the inference computation is configured for a particular artificial neural network with certain aspects adjustable via weights stored in the memory cell array 113. Optionally, the inference logic circuit 123 is implemented via an application-specific integrated circuit (ASIC), a field-programmable gate array (FPGA), or a core of a programmable microprocessor.

In one embodiment, inference logic circuit 123 includes controller 124. In one example, controller 124 manages communications with a host system via interface 125. In one example, controller 124 performs signed or unsigned multiplication using memory cell array 113. In one embodiment, controller 124 selects either signed or unsigned multiplication to be performed based on the type of data to be used as an input for the multiplication. In one example, controller 124 selects signed multiplication in response to determining that inputs for the multiplication are signed.

In FIG. 1, the integrated circuit die 105 having the memory cell array 113 has a bottom surface 133; and the integrated circuit die 109 having the inference logic circuit 123 has a portion of a top surface 134. The two surfaces 133 and 134 can be connected via bonding (e.g., using hybrid bonding) to provide a portion of an interconnect 107 between metal portions on the surfaces 133 and 134.

Similarly, the integrated circuit die 103 having the sensors 111 has a bottom surface 131; and the integrated circuit die 109 having the inference logic circuit 123 has another portion of its top surface 132. The two surfaces 131 and 132 can be connected via bonding (e.g., using hybrid bonding) to provide a portion of the interconnect 107 between metal portions on the surfaces 131 and 132.

An image sensing pixel array of sensors 111 can include a light sensitive element configured to generate a signal responsive to intensity of light received in the element. For example, an image sensing pixel implemented using a complementary metal-oxide-semiconductor (CMOS) technique or a charge-coupled device (CCD) technique can be used.

In some implementations, the image processing logic circuit 121 is configured to pre-process an image from the image sensing pixel array to provide a processed image as an input to the inference computation controlled by the inference logic circuit 123. Optionally, the image processing logic circuit 121 can also use the multiplication and accumulation function provided via the memory cell array 113.

In some implementations, interconnect 107 includes wires for writing image data from the image sensing pixel array to a portion of the memory cell array 113 for further processing by the image processing logic circuit 121 or the inference logic circuit 123, or for retrieval via an interface 125. The inference logic circuit 123 can buffer the result of inference computations in a portion of the memory cell array 113.

The interface 125 of the integrated circuit device 101 can be configured to support a memory access protocol, or a storage access protocol or any combination thereof. Thus, an external device (e.g., a processor, a central processing unit) can send commands to the interface 125 to access the storage capacity provided by the memory cell array 113.

For example, the interface 125 can be configured to support a connection and communication protocol on a computer bus, such as a peripheral component interconnect express (PCIe) bus, a serial advanced technology attachment (SATA) bus, a universal serial bus (USB) bus, a compute express link, etc. In some embodiments, the interface 125 can be configured to include an interface of a solid-state drive (SSD), such as a ball grid array (BGA) SSD. In some embodiments, the interface 125 is configured to include an interface of a memory module, such as a double data rate (DDR) memory module, a dual in-line memory module, etc. The interface 125 can be configured to support a communication protocol such as a protocol according to non-volatile memory express (NVMe), non-volatile memory host controller interface specification (NVMHCIS), etc.

The integrated circuit device 101 can appear to be a memory sub-system from the point of view of a device in communication with the interface 125. Through the interface 125, an external device (e.g., a processor, a central processing unit) can access the storage capacity of the memory cell array 113. For example, the external device can store and update weight matrices and instructions for the inference logic circuit 123, retrieve images generated by an image sensing pixel array of sensors 111 and processed by the image processing logic circuit 121, and retrieve results of inference computations controlled by the inference logic circuit 123.

Integrated circuit die 105 includes a local controller 161 having registers 160. Local controller 161 can perform at least a portion of control functions handled by controller 124. Registers 160 can be set by controller 124 and/or a host to configure memory cell programming adjustments.

Integrated circuit die 109 includes memory 170 having registers 174. In one embodiment, configuration data from a host is received via interface 125. In one example, the configuration data is data used to set registers 174 and/or 160 to configure adjustment of memory cell programming based on a context of memory cells of IC device 101. In one example, this context includes a temperature determined using temperature circuitry 163. In one example, temperature circuitry 163 provides temperatures of memory cells in memory cell array 113. In one example, temperature circuitry 163 is embedded within memory cell array 113.

In one example, the context used to adjust cell programming includes currents measured by sensing circuitry 150. In one example, one or more string currents are measured for pillars of NAND flash memory cells.

In one example, the context used to adjust cell programming includes a time that has elapsed since memory cells have been last programmed. One or more timers 172 are used to monitor this time for memory cells in memory cell array 113.

In one example, the context used to adjust cell programming includes data regarding values of weights stored in memory cells of memory cell array 113. In one example, this data indicates a number of memory cells in an erased state.

In one example, the context used to adjust cell programming includes data obtained from one or more sensors 111. Sensors 111 can include a temperature sensor.

In one example, IC device 101 performs processing for a neural network. The processing includes MVM computations mapped to tiles 141, 142.

In FIG. 1, the interface 125 is positioned, for example, at the bottom side of the integrated circuit device 101, while the image sensor chip is positioned at the top side of the integrated device 101 to receive incident light for generating images.

The voltage drivers 115 in FIG. 1 can be controlled to apply voltages to program the threshold voltages of memory cells in the array 113. Data stored in the memory cells can be represented by the levels of the programmed threshold voltages of the memory cells.

In one example, the interface 125 can be operable for a host system to write data into the memory cell array 113 and to read data from the memory cell array 113. For example, the host system can send commands to the interface 125 to write the weight matrices of the artificial neural network into the memory cell array 113 and read the output of the artificial neural network, the raw data from the sensors 111, or the processed image data from the image processing logic circuit 121, or any combination thereof.

The inference logic circuit 123 and/or controller 161 can be programmable and include a programmable processor, an application-specific integrated circuit (ASIC), or a field-programmable gate array (FPGA), or any combination thereof. Instructions for implementing the computations of the artificial neural network can also be written via the interface 125 into the memory cell array 113 for execution by the inference logic circuit 123.

FIG. 2 shows the computation of a column of weight bits multiplied by a column of input bits to provide an accumulation result according to one embodiment. In FIG. 2, a column of memory cells 207, 217, ..., 227 (e.g., in the memory cell array 113 of an integrated circuit device 101) can be programmed to have threshold voltages at levels representative of weights stored one bit per memory cell.

In alternative embodiments, memory cells in a memory cell array of a DRAM can be programmed to contain stored charges at levels representative of weights stored one bit per memory cell. Such DRAM devices are discussed below.

Voltage drivers 203, 213, ..., 223 (e.g., in the voltage drivers 115 of an integrated circuit device 101) are configured to apply voltages 205, 215, ..., 225 to the memory cells 207, 217, ..., 227 respectively according to their received input bits 201, 211, ..., 221.

For example, when the input bit 201 has a value of one, the voltage driver 203 applies the predetermined read voltage as the voltage 205, causing the memory cell 207 to output the predetermined amount of current as its output current 209 if the memory cell 207 has a threshold voltage programmed at a lower level, which is lower than the predetermined read voltage, to represent a stored weight of one, or to output a negligible amount of current as its output current 209 if the memory cell 207 has a threshold voltage programmed at a higher level, which is higher than the predetermined read voltage, to represent a stored weight of zero.

However, when the input bit 201 has a value of zero, the voltage driver 203 applies a voltage (e.g., zero) lower than the lower level of threshold voltage as the voltage 205 (e.g., does not apply the predetermined read voltage), causing the memory cell 207 to output a negligible amount of current at its output current 209 regardless of the weight stored in the memory cell 207. Thus, the output current 209 as a multiple of the predetermined amount of current is representative of the result of the weight bit, stored in the memory cell 207, multiplied by the input bit 201.

Similarly, the current 219 going through the memory cell 217 as a multiple of the predetermined amount of current is representative of the result of the weight bit, stored in the memory cell 217, multiplied by the input bit 211; and the current 229 going through the memory cell 227 as a multiple of the predetermined amount of current is representative of the result of the weight bit, stored in the memory cell 227, multiplied by the input bit 221.

The output currents 209, 219, ..., and 229 of the memory cells 207, 217, ..., 227 are connected to a common line 241 (e.g., a bitline or source line in tile 141) for summation. In one example, common line 241 is a bitline. A constant voltage (e.g., ground or −1 V) is maintained on the bitline when summing the output currents.

The summed current 231 is compared to the unit current 232, which is equal to the predetermined amount of current, by a digitizer 233 of an analog to digital converter 245 to determine the digital result 237 of the column of weight bits, stored in the memory cells 207, 217, ..., 227 respectively, multiplied by the column of input bits 201, 211, ..., 221 respectively with the summation of the results of multiplications.

The sum of negligible amounts of currents from memory cells connected to the line 241 is small when compared to the unit current 232 (e.g., the predetermined amount of current). Thus, the presence of the negligible amounts of currents from memory cells does not alter the result 237 and is negligible in the operation of the analog to digital converter 245.

In FIG. 2, the voltages 205, 215, ..., 225 applied to the memory cells 207, 217, ..., 227 are representative of digitized input bits 201, 211, ..., 221; the memory cells 207, 217, ..., 227 are programmed to store digitized weight bits; and the currents 209, 219, ..., 229 are representative of digitized results.

The result 237 is an integer that is no larger than the count of memory cells 207, 217, ..., 227 connected to the line 241. The digitized form of the output currents 209, 219, ..., 229 can increase the accuracy and reliability of the computation implemented using the memory cells 207, 217, ..., 227.

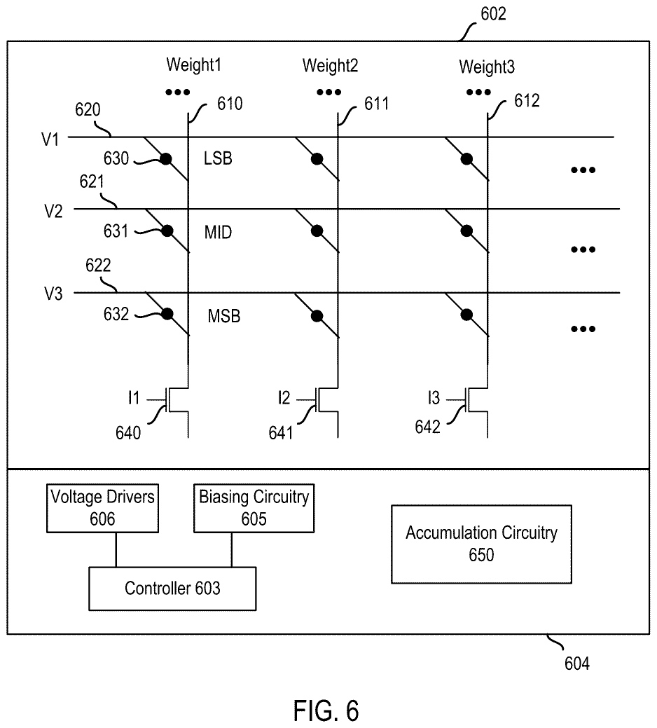

In general, a weight involving a multiplication and accumulation operation can be more than one bit. Memory cells can be used to store the different significant bits of weights (e.g., as illustrated in FIG. 6) to perform multiplication and accumulation operations. The circuit illustrated in FIG. 2 can be considered a multiplier-accumulator unit configured to operate on a column of 1-bit weights and a column of 1-bit inputs. Multiple such circuits can be connected in parallel to implement a multiplier-accumulator unit to operate on a column of multi-bit weights and a column of 1-bit inputs.

The circuit illustrated in FIG. 2 can also be used to read the data stored in the memory cells 207, 217, ..., 227. For example, sensing circuitry 150 can be used to sense a current associated with a memory cell. For example, to read the data or weight stored in the memory cell 207, the input bits 211, ..., 221 can be set to zero to cause the memory cells 217, ..., 227 to output a negligible amount of currents into the line 241 (e.g., as a bitline). The input bit 201 is set to one to cause the voltage driver 203 to apply the predetermined read voltage. Thus, the result 237 from the digitizer 233 provides the data or weight stored in the memory cell 207. Similarly, the data or weight stored in the memory cell 217 can be read via applying one as the input bit 211 and zeros as the remaining input bits in the column; and data or weight stored in the memory cell 227 can be read via applying one as the input bit 221 and zeros as the other input bits in the column.

In general, the circuit illustrated in FIG. 2 can be used to select any of the memory cells 207, 217, ..., 227 for read or write. A voltage driver (e.g., 203) can apply a programming voltage pulse (e.g., one or more pulses or other waveform, as appropriate for a memory cell type) to adjust the threshold voltage of a respective memory cell (e.g., 207) to erase data, to store data or a weight, or to store a charge representing the weight

In general, an input involving a multiplication and accumulation operation can be more than 1 bit. For example, columns of input bits can be applied one column at a time to the weights stored in an array of memory cells to obtain the result of a column of weights multiplied by a column of inputs with results accumulated.

The multiplier-accumulator unit illustrated in FIG. 2 can be implemented in integrated circuit device 101 in FIG. 1.

In one implementation, a memory chip (e.g., integrated circuit die 105) includes circuits of voltage drivers, digitizers, shifters, and adders to perform the operations of multiplication and accumulation. The memory chip can further include control logic configured to control the operations of the drivers, digitizers, shifters, and adders to perform the operations as in FIG. 2.

The inference logic circuit 123 can be configured to use the computation capability of the memory chip (e.g., integrated circuit die 105) to perform inference computations of an application, such as the inference computation of an artificial neural network. The inference results can be stored in a portion of the memory cell array 113 for retrieval by an external device via the interface 125 of the integrated circuit device 101.

Optionally, at least a portion of the voltage drivers, the digitizers, the shifters, the adders, and the control logic can be configured in the integrated circuit die 109 for the logic chip.

The memory cells (e.g., memory cells of array 113) can include volatile memory, or non-volatile memory, or both. Examples of volatile memory include dynamic random-access memory (DRAM) and static random-access memory (SRAM).

Examples of non-volatile memory include flash memory, memory units formed based on negative-and (NAND) logic gates, negative-or (NOR) logic gates, phase-change memory (PCM), magnetic memory (MRAM), resistive random-access memory, cross point storage and memory devices. A cross point memory device can use transistor-less memory elements, each of which has a memory cell and a selector that are stacked together as a column. Memory element columns are connected via two layers of wires running in perpendicular directions, where wires of one layer run in one direction in the layer located above the memory element columns, and wires of the other layer are in another direction and in the layer located below the memory element columns. Each memory element can be individually selected at a cross point of one wire on each of the two layers. Cross point memory devices are fast and non-volatile and can be used as a unified memory pool for processing and storage. Further examples of non-volatile memory include read-only memory (ROM), programmable read-only memory (PROM), erasable programmable read-only memory (EPROM) and electronically erasable programmable read-only memory (EEPROM) memory, etc.

The integrated circuit die 105 and the integrated circuit die 109 can include circuits to address memory cells in the memory cell array 113, such as a row decoder and a column decoder to convert a physical address into control signals to select a portion of the memory cells for read and write. Thus, an external device can send commands to the interface 125 to write weights into the memory cell array 113 and to read results from the memory cell array 113.

In some implementations, the image processing logic circuit 121 can also send commands to the interface 125 to write images into the memory cell array 113 for processing.

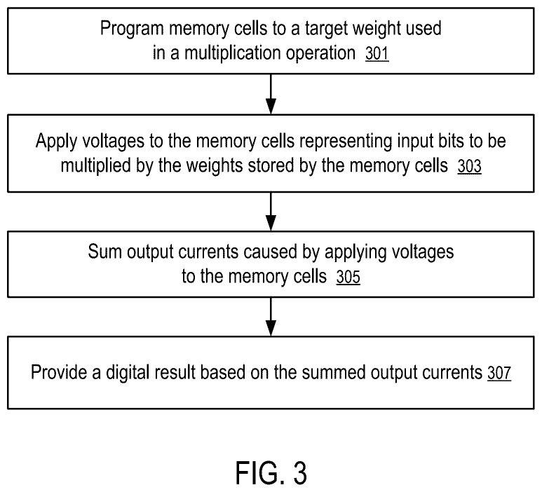

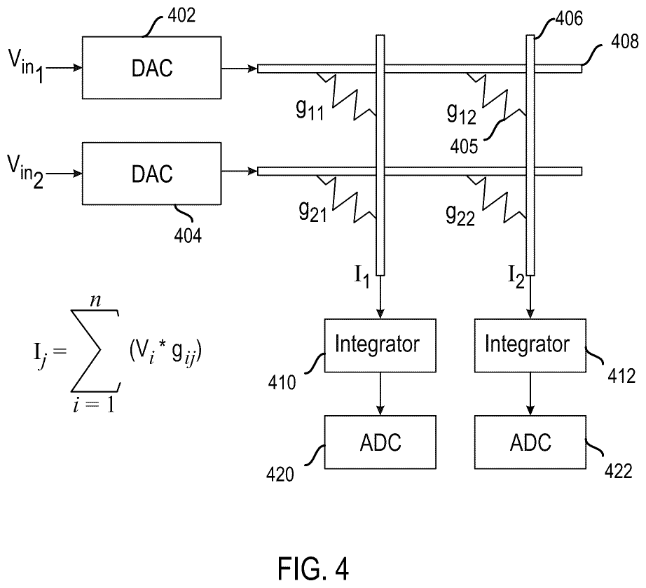

FIG. 3 shows a method of computation in an integrated circuit device based on summing output currents from memory cells according to one embodiment. For example, the method of FIG. 3 can be performed in an integrated circuit device 101 of FIG. 1 using multiplication and accumulation techniques of FIGS. 2, 4, or 6.

The method of FIG. 3 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 3 is performed at least in part by one or more processing devices (e.g., a controller 124 of inference logic circuit 123 of FIG. 1, or local controller 161 of integrated circuit die 105).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 301, memory cells (or sets of memory cells such as 4-cell sets storing a bit of a signed weight) are programmed to a target weight for performing multiplication. In one example, memory cells of memory cell array 113 are programmed. In one example, memory cells 207, 206, 208 are programmed to store weights of different bit significance. The weights correspond to a multi-bit weight (e.g., Weight1 of FIG. 6).

At block 303, voltages are applied to the memory cells. The voltages represent input bits to be multiplied by the weights stored by the memory cells. In one example, voltage drivers apply input voltages 205, 215, 225.

At block 305, output currents from the memory cells caused by applying the voltages are summed. Alternatively, in the case of a DRAM memory cell array, stored charges from the memory cells are accumulated on a sensing line (e.g., digit line and/or bit line) as described below. In one example, the output currents are collected and summed using line 241 as in FIG. 2.

At block 307, a digital result based on the summed output currents is provided. In one example, the summed output currents are used to generate Result X 237 of FIG. 2.

In one embodiment, the device further comprises an interface (e.g., 125) operable for a host system to write data into the memory cell array and to read data from the memory cell array.

In one embodiment, the memory cells include first and second memory cells; the respective weight stored by the first memory cell is a most significant bit (MSB) of a multi-bit weight; and the respective weight stored by the second memory cell is a least significant bit (LSB) of the multi-bit weight.

In one embodiment, the digitizer is configured in an analog-to-digital converter.

FIG. 4 shows an analog weight-stationary architecture for matrix vector multiplication (MVM) according to one embodiment. Because the computational burden is largely on the MVM operation when executing a neural network, an analog weight-stationary architecture is used that focuses on the MVM operation. The other computations/logic required can generally be implemented in the digital and/or analog space since their impact on performance and energy efficiency is relatively small.

In a weight-stationary architecture, the computation is performed where the weights are stored (e.g., performed in a NAND flash memory device or DRAM that stores weights). This removes or reduces the performance bottleneck and power inefficiency of moving the weights out of memory for the computation. The MVM computation is performed in the analog domain. This typically results in some computational error that does not exist in the digital domain.

The weights are stored in storage units 405 (e.g., memory cells) within the memory device (e.g., 101). In one example, the input is sent to an electrode 408 of the storage unit, resulting in a multiplication of the input and the weight (conductance of storage unit based on the stored weight) (e.g., weight of g12 multiplied by input Vin₁). Digital-to-analog converters (DAC) 402, 404 convert digital inputs into magnitudes for analog voltages used to drive electrodes 408 (e.g., an access line such as a select gate drain line).

The result is summed to another electrode (e.g., 406) (e.g., a common line 241 of FIG. 2) within the memory array and detected by an ADC 420, 422. For example, integrators 410, 412 accumulate currents I₁, I₂ from memory cells 405 determined by the conductances of the cells and provide the accumulated currents as inputs to ADC 420, 422.

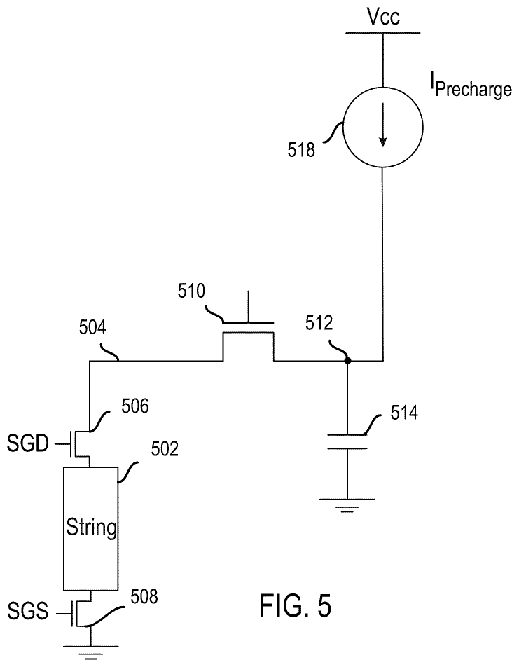

FIG. 5 shows sensing circuitry (e.g., using a sensing amplifier or other sensing circuit) coupled to a bitline 504 used to access NAND flash memory cells according to one embodiment. The sensing circuitry may include an ADC. The memory cells are located in string 502. Select gate drain and source transistors 506, 508 are used to control access to string 502. Select gate transistor 506 is coupled to bitline 504.

The sensing circuitry includes a current source 518 used to pre-charge bitline 504 in preparation for sensing a current (e.g., accumulated output currents) and/or a state of a selected memory cell in string 502. The sensing circuitry is connected to bitline 504 by transistor 510.

During sensing, node 512 is charged, which corresponds to a capacitance 514 (e.g., parasitic capacitance of the sensing circuitry). Bitline 504 is also charged.

In one embodiment, a memory device uses a memory cell array organized as sets of memory cells. In one example, resistive random-access memory (RRAM) cells are used. In one example, NAND or NOR flash memory cells are used.

Each set is programmable to store a multi-bit signed weight. After being programmed, voltage drivers apply voltages (based on adjustment of the voltages using the context of the memory cells) to the memory cells in each set. The voltages represent multi-bit signed inputs to be multiplied by the multi-bit signed weights.

One or more common lines are coupled to each set. The lines receive one or more output currents from the memory cells in each set (e.g., similarly as discussed above for sets of two or four cells). Each common line accumulates the currents to sum the output currents from the sets.

In one example, the line(s) are bitline(s) extending vertically above a semiconductor substrate. As an example, 512 memory cell sets are coupled to the line(s). Inputs are provided using 512 pairs of select lines (e.g., SL+, SL−), with one pair used per set. The output currents from each of the 512 sets are collected on the line(s), and then one or more total current magnitudes are digitized to provide first and second digital values.

In one example, the memory device includes one or more digitizers. The digitizer(s) provide signed results (e.g., as described above) based on summing the output currents from each of the 512 sets on first and second common lines.

A first digital value (e.g., an integer) representing the current on the first common line is determined as the multiple of a predetermined current (e.g., as described above) representing 1. A second digital value representing the current on the second common line is determined as the multiple of the predetermined current. The first and second digital values are, for example, outputs from a digitizer(s).

In one embodiment, a memory device includes a memory cell array having sets of NAND flash memory cells. Each set is programmable to store a multi-bit signed weight. Voltage drivers apply voltages to each set. The voltages correspond to a multi-bit signed input, which is multiplied by the multi-bit signed weight for each set. Two common lines are coupled to each set. Each common line sums a respective output current from each set. A digitizer on each common line provides signed results based on summing the output currents from the sets. Each signed result corresponds to a bit significance of the input and a bit significance of the weight, for example as described above. The signed results are added together taking respective bit significance into consideration to provide first and second digital values that represent a signed accumulation result from the multi-bit to multi-bit multiplication.

In one embodiment, a signed input is applied to a set of memory cells on two wires (e.g., two select lines), each wire carrying a signal. Whether the input is positive or negative depends on where the magnitude of the signal is provided. In other words, the sign depends on which wire carries the signal. The other wire carries a signal of constant value (e.g., a constant voltage corresponding to zero).

Every signed input applied to the set is treated as having a positive magnitude. One of the two wires is always biased as a zero (biased as a constant signal more generally). The other wire carries the magnitude of the input pattern.

In one embodiment, a multi-bit input is represented as a serial or time-sliced input provided on the two wires. For example, the input pattern is a number of bits (e.g., 1101011) for which corresponding voltages are serially applied to the wire, one bit per time slice. In one example, input bits are applied serially one at a time.

In one embodiment, the contribution of output current to common lines from each one of the memory cells varies corresponding to the MSB, MID, or LSB significance of the bit stored by the memory cell (e.g., stored for 3 bits in a group of 3 memory cells above). The contribution for MSB significance (e.g., 100 nA) is two times greater than for MID significance (e.g., 50 nA). The contribution for MID significance is two times greater than for LSB significance (e.g., 25 nA).

When the output current contribution takes bit significance into consideration, then left shifting is not required when adding the signed results (e.g., first, second, third, and fourth signed results) to obtain a signed accumulation result. Instead, the signed results can be added directly without left shifting.

In one embodiment, a memory device performs analog summation of 1-bit result currents having different bit significance implemented via different bias levels. A memory cell (e.g., a RRAM cell or NAND flash memory cell) can be programmed to have exponentially increased (e.g., increasing by powers of two) current for different bias levels.

In one embodiment, a memory cell can be programmed to have a threshold with exponentially increased current for higher bias/applied voltage. A first voltage can be applied to the memory cell to allow a predetermined amount of current (indicated as 1X) to go through to represent a bit value of 1 for the least significant bit.

To represent a bit value of 1 for the second least significant bit, a second voltage can be applied to the memory cell to allow twice (indicated as 2X) the predetermined amount of current to go through, which is equal to the predetermined amount of current multiplied by the bit significance of the second least significant bit.

The memory cell can be similarly biased to have a higher amount of current equal to the predetermined amount of current multiplied by the bit significance of the bit when the bit value is 1.

When different voltages are applied to memory cells each representing one bit in a number such that the respective bit significance of each cell is built into the output currents as described above, the multiplication results involving the memory cells can be summed via connecting them to a line without having to convert the currents for the bits separately for summation.

For example, a 3-bit-resolution weight can be implemented using three memory cells. Each memory cell stores 1-bit of the 3-bit weight. Each memory cell is biased at a separate voltage level such that if it is programmed at a state representing 1, the current going through the cell is a base unit times the bit significance of the cell. For example, the current going through the cell storing the least significant bit (LSB) is a base unit of 25 nA, the cell storing the middle bit (MID) 2 times (2×) the base unit (50 nA), and the most significant bit (MSB) 4 times (4x× the base unit (100 nA).

In one embodiment, a solid-state drive (SSD) or other storage device uses a memory cell array having memory cells. In one example, resistive random-access memory (RRAM) cells are used. In one example, NAND or NOR flash memory cells are used.

In one embodiment, each memory cell is programmable to store one bit of a multi-bit weight. After being programmed, voltage drivers apply different voltages to bias the memory cells for use in performing multiplication. Inputs to be multiplied by the multi-bit weights can be represented by a respective input pattern applied to select gates of select transistors coupled to the memory cells (e.g., as described above), or by varying the different voltages between a fixed voltage state representing an input bit of 1 and a zero state representing an input bit of 0.

One or more common or sensing lines are coupled to the memory cells. The lines receive one or more output currents from the memory cells (e.g., as described above). Each common or sensing line (e.g., bitline) is used to accumulate the currents to sum the output currents.

In one embodiment, three memory cells store values representing three bits of a stored weight. One bit is for an MSB, one bit is for a bit of middle significance (sometimes indicated as “MID” herein), and one bit is for an LSB. This provides a multi-bit representation for the stored weight.

FIG. 6 shows an architecture having resistive random access memory (RRAM) or NOR memory cells arranged in a parallel configuration for performing multiplication (e.g., MVM) according to one embodiment. For example, memory cells 630, 631, 632 of memory cell array 602 store bits of respective significance for a multi-bit weight (indicated as Weight1). A simple 3-bit weight is illustrated, but a larger number of bits can be stored for each weight. When performing multiplication, each of memory cells 630, 631, 632 can be accessed in parallel. In one example, memory cell array 602 includes memory cells arranged as illustrated in FIG. 6.

Each memory cell provides an output current that corresponds to a significance of a bit stored by the memory cell. Memory cells 630, 631, 632 are connected to a common line (sometimes referred to herein as a sensing line) 610 for accumulating output currents. In one example, line 610 is a bitline.

Different voltages V1, V2, V3 are applied to memory cells 630, 631, 632 using wordlines 620, 621, 622. Voltages are selected so that the output currents vary by a power of two based on bit significance, for example as described above.

In one embodiment, an input signal I1 is applied to the gate of select transistor 640. Select transistor 640 is coupled to common line 610. An output of select transistor 640 provides a sum of the output currents. In one embodiment, when the input signal is applied to the gate of select transistor 640, the different voltages V1, V2, V3 are held at a constant voltage level.

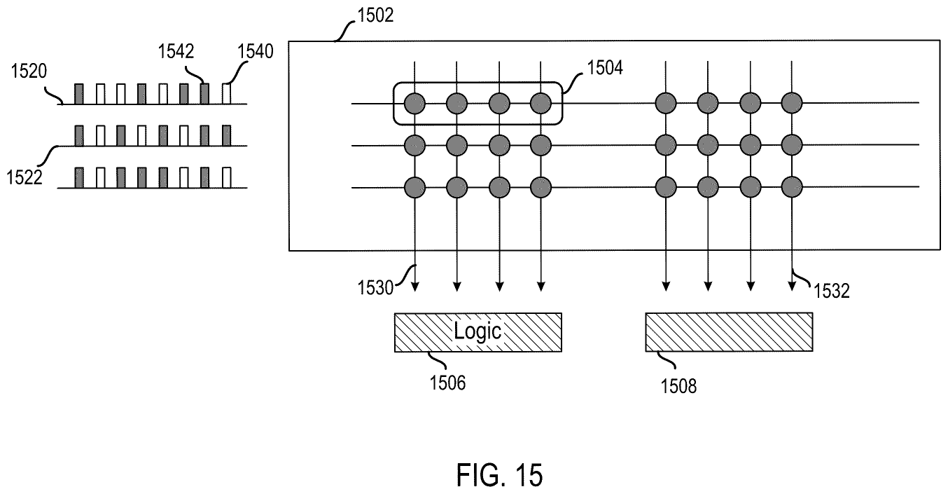

In an alternative embodiment, an input pattern for multiplication by Weight1 can be applied to wordlines 620, 621, 622 by varying the different voltages V1, V2, V3 between fixed voltages and zero voltages similarly as described above to represent input bits of 1 or 0, respectively. In one embodiment, the input pattern can be applied in a series of time slices (see, e.g., the input bit stream of FIG. 15).

Memory cell array 602 is formed above semiconductor substrate 604. In one embodiment, memory cell array 602 and semiconductor substrate 604 are located on different chips or wafers prior to being assembled (e.g., being joined by bonding).

Similarly, as described above for Weight1, multi-bit weights Weight2 and Weight3 can be stored in other memory cells of memory cell array 602, and output currents accumulated on common lines 611, 612, as illustrated. These other memory cells can be accessed using wordlines 620, 621, 622. Common lines 611, 612 are coupled to select transistors 641, 642, which each provide a sum of output currents as an output. Input patterns I2, I3 can be applied to gates of the select transistors. Additional weights can be stored in memory cell array 602.

Output currents from common lines 610, 611, 612 are accumulated by accumulation circuitry 650. In one embodiment, accumulation circuitry 650 is formed in semiconductor substrate 604 (e.g., formed at a top surface).

In one embodiment, voltage drivers 606 and biasing circuitry 605 are formed in semiconductor substrate 604. Logic circuitry (not shown) formed in semiconductor substrate 604 is used to implement controller 603. Controller 603 controls voltage drivers 606 and biasing circuitry 605.

In one embodiment, voltage drivers 606 provide the different voltages V1, V2, V3. Each voltage is adjusted based on a context of the memory cell array determined by a controller (e.g., 124, 161). Biasing circuitry 605 applies inputs I1, I2, I3.

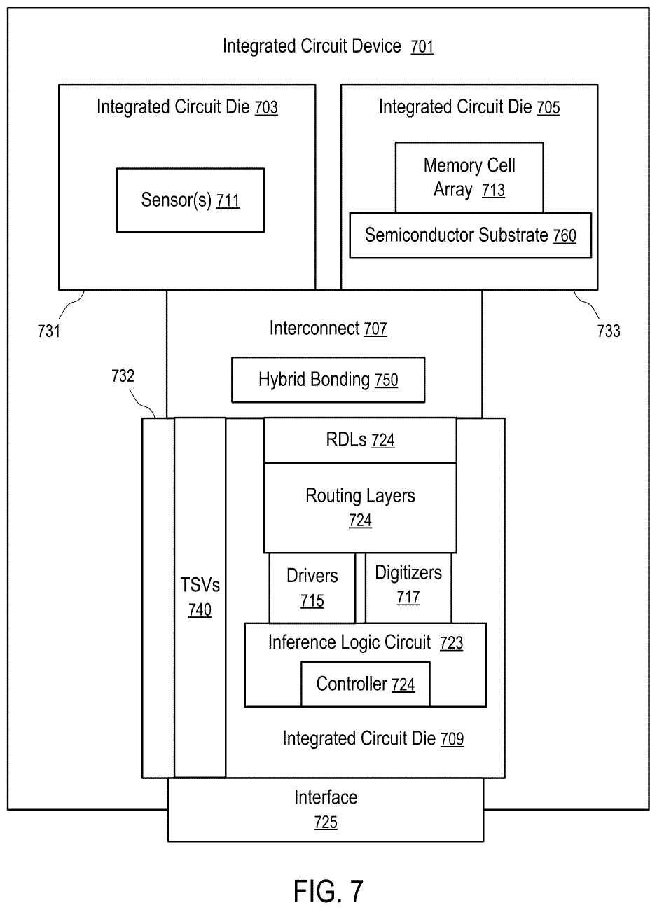

FIG. 7 shows a memory device (e.g., integrated circuit device 701) having integrated circuit (IC) dies 703, 705, 709 that are bonded together for use in performing multiplication operations according to one embodiment. IC device 701 is an example of IC device 101 of FIG. 1.

IC dies 703, 705, 709 are connected by interconnect 707. In one embodiment, interconnect 707 is formed by hybrid bonding 750. Interconnect 707 permits communication of signals amongst IC dies 703, 705, 709. Interconnect 707 is an example of interconnect 107.

Hybrid bonding is also known as heterogeneous direct bonding or copper hybrid bonding. In one embodiment, hybrid bonding 750 is a type of chemical bonding between two surfaces of material meeting various requirements. Direct bonding of a wafer typically includes pre-processing wafers, pre-bonding the wafers at room temperature, and annealing at elevated temperatures. For example, direct bonding can be used to join two wafers of a same material (e.g., silicon); anodic bonding can be used to join two wafers of different materials (e.g., silicon and borosilicate glass); eutectic bonding can be used to form a bonding layer of eutectic alloy based on silicon combining with metal to form a eutectic alloy.

Hybrid bonding can be used to join two surfaces having metal and dielectric material to form a dielectric bond with an embedded metal interconnect from the two surfaces. The hybrid bonding can be based on adhesives, direct bonding of a same dielectric material, anodic bonding of different dielectric materials, eutectic bonding, thermocompression bonding of materials, or other techniques, or any combination thereof.

Interconnect 707 electrically and physically connects to various input/output pads (not shown) on surfaces 731, 732, 733 of the IC dies. In some cases, to assist with forming and/or aligning electrical connections to interconnect 707, redistribution layers (RDLs) 724 are located at surface 732 of IC die 709. Redistribution layers 724 are connected to at least a portion of the input/output pads. Redistribution layers (not shown) can also be used at surfaces 731, 733 of IC dies 703, 705.

IC die 705 has a memory cell array 713. Memory cells (not shown) of array 713 store weights to be used in multiplication and/or other operations. Memory cell array 713 is formed above a semiconductor substrate 760. In one example, memory cell array 713 has memory cells arranged as multiple tiers stacked vertically above semiconductor substrate 760.

IC die 703 has one or more sensors 711. In one example, sensor 711 is an image sensor. Other sensors such as Lidar, radar, temperature, GPS, and/or accelerometer sensors can be used. One or more of the sensors 711 provide data used to form input vectors to be multiplied by weights stored in memory cell array 713.

In some embodiments, vector matching is performed using the input vectors to determine further processing to be done using the input vectors. For example, the further processing can be selection of a particular layer of a neural network based on results from the vector matching. In one example, the further processing can be selection of memory cell array 713 to be used for multiplication by one or more of the input vectors (instead of sending the input vectors to the host for processing).

IC die 709 includes inference logic circuit 723. In one embodiment, logic circuit 723 includes controller 724. Logic circuit 723 is an example of inference logic circuit 123. Controller 724 is an example of controller 124.

Logic circuit 723 controls the determination of a sum of products with 4-quadrant multiplication or 2-quadrant multiplication or 1-quadrant multiplication, vector matching, and/or bitwise exclusive or (XOR) or exclusive nor (XNOR) operations performed using memory cell array 713. Logic circuit 723 also manages communications of signals between any or all of IC dies 703, 705, and/or 709.

IC die 709 has routing layers 724. In one embodiment, routing layers 724 provide a communication path(s) for signals from one group of memory cells of memory cell array 713 to another group of memory cells of memory cell array 713. One or more routing layers 724 can be electrically coupled to redistribution layers 724 as part of this communication path(s).

In one embodiment, IC die 709 includes voltage drivers 715 and digitizers 717. Voltage drivers 715 are an example of voltage drivers 203, 213, 223. Digitizers 717 are an example of digitizer 233.

In one embodiment, voltage drivers 715 are used to apply voltages to memory cells in memory cell array 713. Routing layers 724 and interconnect 707 electrically connect voltage drivers 715 and/or digitizers 715 to memory cell array 713.

In one embodiment, IC dies 703, 705, 709 are encapsulated in a single package. Interface 725 permits external communications with a host computing device. Interface 725 is an example of interface 125. For example, controller 724 can receive commands and/or data from the host, and/or send results and/or data to the host over interface 725.

In one embodiment, through silicon vias (TSVs) 740 connect interconnect 707 to interface 725. For example, a host can communicate directly with IC die 703 and/or 705 using TSVs 740. In one example, power can be supplied externally and directly to IC die 703 and/or 705 using TSVs 740.

In one embodiment, a device comprises: a first integrated circuit (IC) die (e.g., 105, 705) having a memory cell array (e.g., 113) including memory cells, wherein the memory cells are programmable to store at least one weight; and a second IC die (e.g., 109, 709) having logic circuitry (e.g., inference logic circuit 723) configured to perform multiplication or bitwise XOR operations using the stored weights and various inputs.

The second IC die is bonded to the first IC die (e.g., using chip to wafer bonding, or wafer to wafer bonding), and the logic circuitry is further configured to determine at least one result from the multiplication or a bitwise XOR operation based on summing output currents from at least a portion (e.g., a tile or layer) of the memory cells.

In one embodiment, the first and second IC dies are connected using hybrid bonding (e.g., 750).

In one embodiment, the hybrid bonding comprises connecting the first and second IC dies by combining a dielectric bond (e.g., SiOx) with an embedded metal (e.g., Cu) to form an interconnect (e.g., 707, or interconnect 107 of FIG. 1) between the first and second IC dies.

In one embodiment, the interconnect (e.g., 707) is electrically coupled to through silicon vias (TSVs) (e.g., 740) used to communicate with a host device (e.g., a host device on a third IC die bonded to the second IC die).

In one embodiment, the logic circuitry is further configured to generate at least one pulsing sequence (e.g., a multi-bit input, a column vector of bits, or a time series of bits) that represents the input.

In one embodiment, the second IC die further has an interface (e.g., 725) used to communicate with a host system.

In one embodiment, the second IC die further has: at least one routing layer (e.g., 724); and a controller configured to communicate, using the routing layer, results from first memory cells of the memory cell array to second memory cells of the memory cell array.

In one embodiment, the second IC die further has at least one digitizer (e.g., analog to digital converter) used to generate the at least one result.

In one embodiment, the device further comprises an interconnect between the first and second dies formed by hybrid bonding. At least one of the first or second IC dies further has at least one redistribution layer (e.g., 724) electrically connected to the interconnect, and the redistribution layer is configured to electrically connect first memory cells of the memory cell array to the logic circuitry (e.g., 123, 723).

In one embodiment, the first IC die includes a semiconductor substrate (e.g., 760); the memory cell array includes a column of first memory cells connected to a common or sensing line to accumulate first output currents from the first memory cells; the column of first memory cells extends vertically above the semiconductor substrate with the first memory cells arranged in a plurality of tiers (e.g., the memory cells are formed using semiconductor processing layers for each tier); and the first memory cells store a first weight (e.g., multiple tiers of cells store multiple bits of a weight).

In one embodiment, the first IC die includes a semiconductor substrate (e.g., 760); the memory cell array is configured as a DRAM and includes a column of first memory cells connected to a sensing line to accumulate output charges from the first memory cells; the column of first memory cells extends vertically above the semiconductor substrate with the first memory cells arranged in a plurality of tiers (e.g., the memory cells are formed using semiconductor processing layers for each tier); and the first memory cells store a first weight (e.g., multiple tiers of cells store multiple bits of a weight).

In one embodiment, the memory cells are resistive random-access memory (RRAM) cells, DRAM cells, NAND flash memory cells, or NOR flash memory cells.

In one embodiment, the memory cells are resistive random-access memory (RRAM) cells (e.g., chalcogenide memory cells) arranged in vertical tiers extending above a semiconductor substrate, and the memory cell array further includes a respective selector or select transistor in series with each RRAM cell, wherein the selectors are configured for selecting RRAM cells on any one or more of the tiers, and wherein the RRAM cells are selected based on a multiplication or bitwise XOR operation to be performed.

In one embodiment, an apparatus comprises: a memory cell array (e.g., 713) comprising memory cells programmable to store vectors (e.g., image data from sensors 711). The memory cells are organized in horizontal tiers of cells, and the tiers are stacked vertically above a semiconductor substrate. Voltage drivers are configured to apply voltages to the memory cells.

The voltages represent input vectors to be applied to the memory cells when performing vector matching. At least one line is coupled to the memory cells. The line is configured to sum output currents from the memory cells.

A logic circuit is configured to provide a first result based on the summed output currents for a first input vector. The first result indicates an extent of matching of the first input vector to the stored vectors.

In one embodiment, the logic circuit is further configured to calculate a Hamming distance based on the first result.

In one embodiment, a magnitude of the summed output currents for the first input vector corresponds to the extent of matching (e.g., input vectors and stored vectors are inverted so that a magnitude of the summed output currents increases as the extent of matching decreases; if there is an exact vector match, then the summed output currents are zero or a negligible amount such as a leakage current). In this context, XOR and XNOR are interchangeable. For example, a sum of bitwise XOR measures the extent of mismatches, while a sum of bitwise XNOR measures the extent of matching. A Hamming distance measures the extent of matching.

In one embodiment, the first result is a Hamming distance calculated for the first input vector; the logic circuit comprises a controller (e.g., 724); and the controller (e.g., 724) is configured to select a portion of a neural network (e.g., a neural network represented by weights stored in memory cells of array 713) for inference using the first input vector based on the calculated Hamming distance.

In one embodiment, a layer in a neural network is selected for further processing of the first input vector based on the first result. In one example, the layer is selected from layers of a neural network model having a portion of the model stored in memory cell array 713, and another portion of the model stored in a host communicating with controller 724 using interface 725.

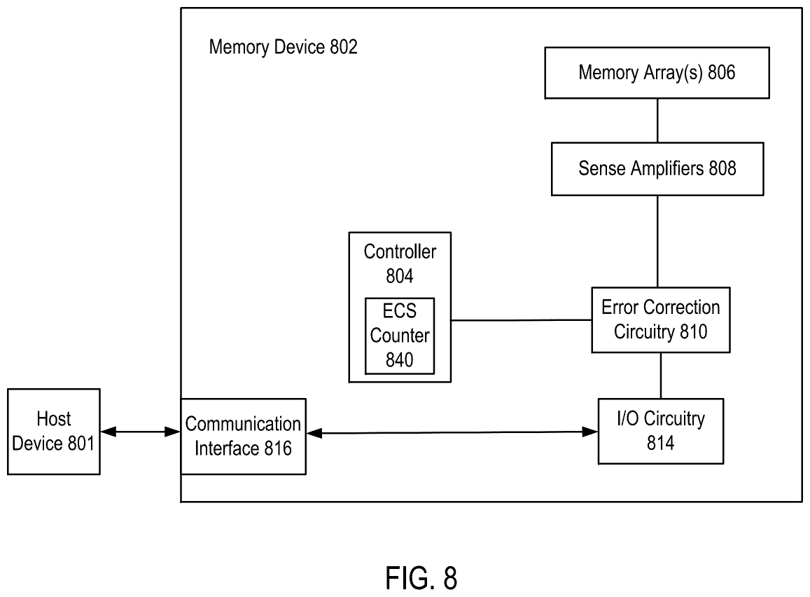

FIG. 8 shows a memory device 802 storing data in one or more memory arrays 806 for a host device 801 according to one embodiment. In one example, memory device 802 is a dynamic random access memory. Memory array 806 includes memory cells each storing a charge corresponding to a weight or partial weight for a neural network. In one example, memory array 806 is configured using resistive random access memory cells.

In one embodiment, error correction circuitry 810 services memory management operations performed on data stored in memory array(s) 806. Portions of data from memory array 806 are copied to temporary storage (e.g., a buffer) during this servicing.

In one example, the temporary storage includes scrub holding registers. In one example, error correction circuitry 810 is an ECC engine.

While data is being serviced by the ECC engine, the data is stored in the temporary storage. In one example, the data has been copied from a source page of memory array 806 using sense amplifiers 808. In some cases, write operations will be performed by controller 804 and/or host device 801 to the address location of the source page that is being serviced. Indications are stored regarding any such write operations that occur. These indications are stored as status data.

In one embodiment, ECS counter 840 points to one or more rows of memory array 806. Code words stored in these rows are moved to one or more scrub holding registers in temporary storage. Error correction circuitry 810 scrubs the code words in the temporary storage. Controller 804 can perform read and/or write operations on various rows in array 806 and does error correction on read or write data using error correction circuitry 810.

After scrubbing the code words stored in temporary storage, controller 804 writes back one or more scrubbed code words (e.g., to the rows pointed to by ECS counter 840).

In one embodiment, memory device 802 is a DRAM device that uses an error check and scrub (ECS) mode. On a periodic basis, controller 804 grabs data from a certain row in the array, scrubs the data with an ECC engine, and then puts the data back to that row. The certain row is pointed to by the ECS counter 840. A main ECC engine (e.g., error correction circuitry 810) is shared among multiple banks for reads and writes. The ECS counter 840 is incremented as rows are scrubbed so that all rows in array 806 are scrubbed within a defined time period (e.g., every 24 hours).

Error correction circuitry 810 services read and write operations. For example, the read or write operations are performed in response to commands or other signals received from host device 801.

Controller 804 accesses portions of memory array(s) 806 in response to commands received from host device 801 via communication interface 816. Sense amplifiers 808 sense data stored in memory cells of memory arrays 806. Controller 804 accesses the stored data by activating one or more rows of memory arrays 806. In one example, the activated rows correspond to a page of stored data.

When a row of memory array 806 is activated, data can be read from the row as part of a read or other operation (e.g., scrubbing for ECS operations, wear leveling). Error correction circuitry 810 is used to detect and correct any errors identified in the accessed data on the row for a read requested by host device 801. Corrected read data is provided for output on communication interface 816 by I/O circuitry 814.

In one embodiment, communication interface (I/F) 816 is a bi-directional parallel or serial communication interface. The host device 801 can include a host processor (e.g., a host central processing unit (CPU) or other processor or processing circuitry, such as a memory management unit (MMU), interface circuitry, etc.).

In one embodiment, memory arrays 806 can be configured in a number of non-volatile memory devices (e.g., dies or LUNs), such as one or more stacked flash memory devices each including non-volatile memory (NVM) having one or more groups of non-volatile memory cells and a local device controller or other periphery circuitry thereon (e.g., device logic, etc.), and controlled by controller 804 over an internal storage-system communication interface (e.g., an Open NAND Flash Interface (ONFI) bus, etc.) separate from the communication interface 816.

In one embodiment, each memory cell in a NOR, NAND, 3D Cross Point, MRAM, DRAM, or one or more other architecture semiconductor memory array 806 can be programmed individually or collectively to one or a number of programmed states. A single-level cell (SLC) can represent one bit of data per cell in one of two programmed states (e.g., 1 or 0). A multi-level cell (MLC) can represent two or more bits of data per cell in a number of programmed states (e.g., 2ⁿ, where n is the number of bits of data). In certain examples, MLC can refer to a memory cell that can store two bits of data in one of 4 programmed states. A triple-level cell (TLC) can represent three bits of data per cell in one of 8 programmed states. A quad-level cell (QLC) can represent four bits of data per cell in one of 16 programmed states. In other examples, MLC can refer to any memory cell that can store more than one bit of data per cell, including TLC and QLC, etc.

The controller 804 can receive instructions from the host device 801, and can transfer data to (e.g., write or erase) or from (e.g., read) one or more of the memory cells of the memory arrays 806. The controller 804 can include, among other things, circuitry or firmware, such as a number of components or integrated circuits. For example, the controller 804 can include one or more memory control units, circuits, or components configured to control access across the memory array and to provide a translation layer between the host device 801 and a storage system, such as a memory manager, one or more memory management tables, etc.

In one embodiment, controller 804 can include circuitry or firmware, such as a number of components or integrated circuits associated with various memory management functions, including, among other functions, error check and scrub, wear leveling, error detection or correction, bank or block retirement, or one or more other memory management functions.

In one embodiment, controller 804 can include a set of management tables configured to maintain various information associated with one or more components of memory device 802 (e.g., various information associated with a memory array or one or more memory cells coupled to controller 804). For example, the management tables can include information regarding bank or block age, block erase count, error history, or one or more error counts (e.g., a write operation error count, a read bit error count, a read operation error count, an erase error count, etc.) for one or more banks or blocks of memory cells coupled to the controller 804. In certain examples, if the number of detected errors for one or more of the error counts is above a threshold, the bit error can be referred to as an uncorrectable bit error. The management tables can maintain a count of correctable or uncorrectable bit errors, among other things.

In one embodiment, memory device 802 can include one or more three-dimensional (e.g., 3D NAND or DRAM) architecture semiconductor memory arrays 806. The memory arrays 806 can include a number of memory cells arranged in, for example, banks, a number of devices, planes, blocks, physical pages, super blocks, or super pages. As one example, a TLC memory device can include 18,592 bytes (B) of data per page, 1536 pages per block, 548 blocks per plane, and 4 planes per device.

In one embodiment, data can be written to or read from the memory device 802 in pages. However, one or more memory operations (e.g., read, write, erase, etc.) can be performed on larger or smaller groups of memory cells, as desired. For example, a partial update of tagged data from an offload unit can be collected during data migration or garbage collection to ensure it was re-written efficiently.

In one example, a page of data includes a number of bytes of user data (e.g., a data payload) and its corresponding metadata. As an example, a page of data may include 4 kB of user data as well as a number of bytes (e.g., 32 B, 54 B, 224 B, etc.) of auxiliary or metadata corresponding to the user data, such as integrity data (e.g., error detecting or correcting code data), address data (e.g., logical address data, etc.), or other metadata associated with the user data. Different types of memory cells or memory arrays can provide for different page sizes, or may require different amounts of metadata associated therewith.

In one example, a page is accessed by activating a row in memory array 806. The error in the accessed page is detected using error correction circuitry. In one embodiment, one or more parity bits are used to check for errors in the page. Other error detection schemes can be used in other embodiments.

In one example, the page contains multiple code words 0, 1, ... 2ⁿ−1. In one embodiment, data stored in the code words of the page includes both user data and parity data stored for each code word.

Each page in the memory array has multiple columns [n:0]. Data being read from or written to the page is addressed by a row address and a column address. The row address corresponds to a wordline that is activated to access data stored in the page. The column address is used by a column decoder to select a column for memory cells containing the data to be accessed.

During a read operation, data read from the page is processed by an ECC engine to detect and correct errors. Corrected data is, for example, communicated to a host device via a data path to input/output pins (e.g., DQ pins).

In one embodiment, each code word of the page includes user data (e.g., Data 0) and a parity (e.g., Parity 0) previously calculated for that data. In one example, the parity is an error correction code providing a capability to correct one or more bits of the code word. The parity stored for each code word can be computed by an ECC engine when the code word is stored. The ECC engine can use the parity stored for each code word to detect and correct one or more bit errors of the code word when the code word is being read.

In one example, when an activate command is issued, the page is sensed, and the page's data is stored in sense amplifier latches.

In one example, a memory management operation is allocated to scrub the page data. The scrub uses error correction circuitry where each code word is scrubbed one at a time (e.g., the corrected data is written back into the scrub holding register one code word at a time). Data transfer from the DQ (input/output) pins of the memory device involves use of error correction circuitry.

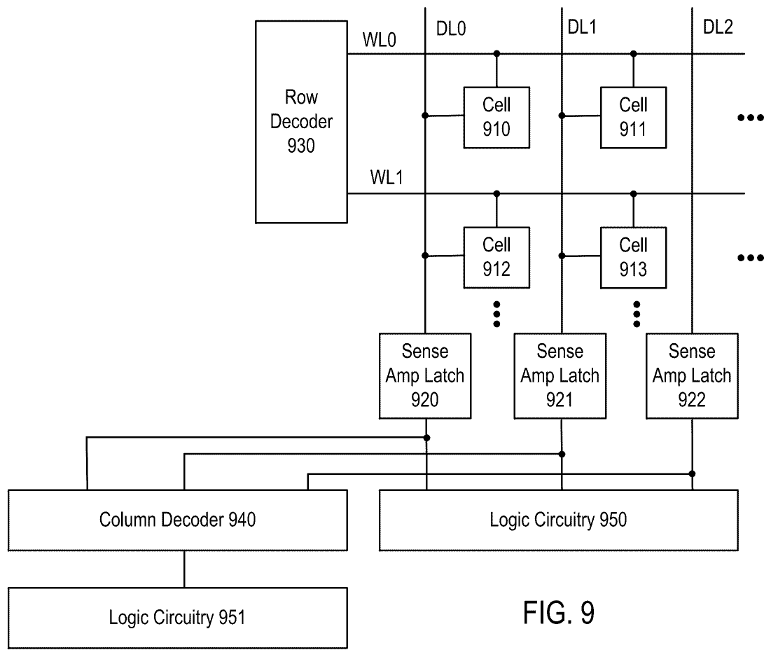

FIG. 9 shows sense amplifier latches 920, 921, 922 to hold data associated with memory cells 910, 911, 912, 913 of a memory array, in accordance with some embodiments. In one example, the memory cells are located in memory array 106. The memory cells can be of various memory types including volatile and/or non-volatile memory cells. In one example, the memory cells store charge in a DRAM memory array.

The memory cells are accessed using wordlines (e.g., WL0) and digit lines (e.g., DL0) or bit lines. An individual memory cell is accessed by activating a wordline selected by row decoder 930 and selecting a digit line or bit line selected by column decoder 940. When a wordline is activated, data from each memory cell on a row resides in the corresponding sense amplifier latch for each digit line or bit line.

Data residing in the sense amplifier latches can be used as inputs to logic circuitry 950, 951 for various computations. These can include using parity or other metadata stored with the memory cells to detect and/or correct errors in the data retrieved from the memory cells. In one embodiment, logic circuitry 950 includes error correction circuitry 110. In one example, logic circuitry 950 is arbitrary logic that operates on data at the page level.

Logic circuitry 951 is coupled to column decoder 940. In one embodiment, logic circuitry includes error correction circuitry 110. In one example, logic circuitry 951 is arbitrary logic that operates on data at the column (e.g., code word) level (e.g., using an ECC engine).

In one embodiment, a memory device including a memory array has a plurality of memory cells 910, 911, 912, 913, etc., and one or more circuits or components to provide communication with, or perform one or more memory operations on, the memory array. A single memory array or additional memory arrays, dies, or LUNs can be used. The memory device can include row decoder 930, column decoder 940, sense amplifiers, a page buffer, a selector, an input/output (I/O) circuit, and a controller.

In some non-volatile memory devices (e.g., NAND flash), the memory cells of the memory array can be arranged in blocks. Each block can include sub-blocks. Each sub-block can include a number of physical pages, each page including a number of memory cells. In some examples, the memory cells can be arranged in a number of rows, columns, pages, sub-blocks, blocks, etc., and accessed using, for example, access lines, data lines, or one or more select gates, source lines, etc.

In volatile memory devices (e.g., DRAM) and some emerging non-volatile memory technologies, the memory cells of the memory array can be arranged in banks or other forms of partition. In one example, when an activation to a row address is issued, the row address may be addressed by addressing bits on the activate command using a bank address (to specify which bank within the memory device), and a row address (to specify which row within the specified bank). The wordline associated with the row address is brought high.

A controller (e.g., controller 804) can control memory operations of the memory device according to one or more signals or instructions received on control lines (e.g., from host device 801) including, for example, one or more clock signals or control signals that indicate a desired operation (e.g., write, read, erase, etc.), or address signals (A0-AX) received on one or more address lines. One or more devices external to the memory device can control the values of the control signals on the control lines, or the address signals on the address line. Examples of devices external to the memory device can include, but are not limited to, a host, a memory controller, a processor, or one or more circuits or components.

The memory device can use access lines and data lines to transfer data to (e.g., write or erase) or from (e.g., read) one or more of the memory cells. The row decoder and the column decoder can receive and decode the address signals (A0-AX) from the address line, can determine which of the memory cells are to be accessed, and can provide signals to one or more of the access lines (e.g., one or more of a plurality of wordlines (e.g., WL0-WLm)) or the data lines (e.g., one or more of a plurality of bit lines (BL0-BLn).

The memory device can include sense circuitry, such as sense amplifiers 808, configured to determine the values of data on (e.g., read), or to determine the values of data to be written to, the memory cells using the data lines. In one example, sense amplifiers are used to sense voltage (e.g., in the case of charge sharing in DRAM). In one example, in selected memory cells, one or more of the sense amplifiers can read a logic level in the selected memory cell in response to a read current flowing in the memory array through the selected cell(s) to the data line(s).

One or more devices external to the memory device can communicate with the memory device using I/O lines (e.g., DQ0-DQN), address lines (e.g., A0-AX), or control lines. I/O circuitry (e.g., 814) can transfer values of data in or out of the memory device, such as in or out of the page buffer or the memory array, using the I/O lines, according to, for example, the control lines and address lines. The page buffer can store data received from the one or more devices external to the memory device before the data is programmed into relevant portions of the memory array, or can store data read from the memory array before the data is transmitted to the one or more devices external to the memory device.

The column decoder 940 can receive and decode address signals (e.g., A0-AX) into one or more column select signals (e.g., CSEL1-CSELn). The selector (e.g., a select circuit) can receive the column select signals (CSEL1-CSELn) and select data in the page buffer representing values of data to be read from or to be programmed into memory cells. Selected data can be transferred between the page buffer and the I/O circuitry.

Various embodiments related to a dynamic random access memory (DRAM) device used to perform artificial intelligence (AI) computations (e.g., MVM) are now described below. In one embodiment, the DRAM stores weights to be multiplied by input vectors. In one example, the weights are for a neural network and the input vectors are based on data collected by one or more sensors, or derived from previous layers of the neural network. The generality of the following description is not limited by the various embodiments described above.

Matrix vector multiplication (MVM) is a fundamental array operation when using AI models for inference and training. The majority of the compute energy in such applications is consumed by moving data for the MVM operations from a DRAM component to dedicated MVM engines (e.g., located on a different chip in a standard GPU architecture). There is a need to reduce this compute energy.

In one example, the energy required for computation when using large language models is significant and primarily due to moving data to and from memory. There is a need to perform more computations locally to reduce this energy consumption.

Various embodiments described below provide a technical solution to the above energy problem by execution of the MVM operations directly on a DRAM array to provide an MVM result. The bandwidth requirements to send this MVM result to, for example, a GPU for further processing is reduced.

In one embodiment, a DRAM device includes first memory cells storing weights to use for MVM. The DRAM device includes second memory cells that act as mirror cells and store the identical state of charge stored by corresponding ones of the first memory cells. During an MVM operation, a controller accumulates charge stored in the first memory cells. The accumulated charge is used to provide a result. After accumulating the charge to provide the result, the controller restores the first memory cells to their original state based on the charge stored in the corresponding one of the second memory cells.

A DRAM array includes a sensing line (e.g., a digit line) that is connected to the first memory cells and the second memory cells using select transistors. The sensing line is used to accumulate the charge from the first memory cells during MVM.

The controller restores the original state of the first memory cells by determining corresponding states of the second memory cells and replicating each respective state to the first memory cells.

In one embodiment, a controller accumulates charge from a plurality of memory cells in parallel using a common sensing line. The controller determines a magnitude of the accumulated charge. The magnitude corresponds to the value of the result. In one example, a capacitor in sensing circuitry is pre-charged, and the magnitude is determined by incrementing a counter as the sensing line is charged in small pulses using charge from the capacitor.

In one embodiment, a DRAM array includes a plurality of tiles. Each tile has corresponding sensing circuitry. A controller receives weights from a host. The controller stores the weights in the DRAM array by replicating the weights into the tiles. The extent of weight replication is selected by the controller based on a number of input streams to be processed in parallel.

In one embodiment, MVM on a DRAM device is enabled by parallel selection of multiple wordlines per sensing line (e.g., a digit line or bit line). Parallel selection of multiple tiles of an array is done as needed to support a desired size of the MVM array.

In one embodiment, MVM on a DRAM device is enabled by using enhanced sensing circuits to support an analog-to-digital conversion function to generate partial sums. Sensing circuits used for the MVM may be distinct from DRAM sense circuits for conventional read or write operations, or may share functionality.

In one embodiment, MVM on a DRAM device is enabled by using accumulation circuits that aggregate the partial sums of low-resolution ADCs into higher resolution results.

In one embodiment, MVM on a DRAM device is enabled by providing sets of mirror cells connected to the same sensing lines as those memory cells involved in a parallel MVM calculation. Use of the mirror cells enables writeback of the discharged memory cells to their previous state so that a subsequent MVM calculation can be supported using the same memory cells. Multiple writeback cycles may be required depending on the number of parallel wordlines selected during MVM.

In one embodiment, MVM on a DRAM device is enabled by using a protocol or instruction set and logic to trigger the MVM calculation functionality. In one example, this is an enhancement to a standard DRAM protocol.

In various embodiments, the DRAM device above can be implemented using planar or three-dimensional memory array structures (e.g., as described above). Memory cells can store a single bit per cell, or multilevel cells (e.g., TLC or QLC) can be used. The DRAM device can be formed using monolithic or bonded technologies (e.g., hybrid bonding).

FIG. 10 shows a sensing line 1006 used to accumulate charge from memory cells according to one embodiment. In one example, the memory cells are configured in memory cell array 113. In one example, the memory cells are configured in one or more memory arrays 806.

The illustrated memory cells form a portion of a DRAM memory array. Memory cells 1002, 1003 store data that is used during MVM processing. In one example, the stored data are bits representing weights received from host device 801.

Memory cells 1004, 1005 act as mirror cells to mirror the state of charge stored in memory cells 1002, 1003. The mirror cells are used to writeback the state of the memory cells 1002, 1003 that existed prior to performing MVM.

The memory cells storing weights and corresponding mirror cells are connected to a sensing line 1006 (e.g., a digit line) by select transistors 1008, 1010. The select transistors are turned on and off by wordlines 1012, 1014.

Sensing line 1006 is used to accumulate charge stored by memory cells 1002, 1003 during MVM. The charge is accumulated by sensing circuitry (not shown) coupled to sensing line 1006.

Each memory cell stores charge in a capacitor or container of the cell. The memory cell has terminals connected to the select transistors and to a common plate voltage PL.

In general, the sensing line 1006 is any network of digit lines, global digit lines, local digit lines, bit line segments, bit lines, local bit lines, access lines, etc. that are used to access the memory cells and accumulate stored charge from the memory cells used in an MVM.

When performing MVM, a controller uses wordlines 1012 to turn on select transistors 1008 to select memory cells 1002, 1003. The controller uses wordlines 1014 to turn off select transistors 1010. Charge stored in mirror cells 1004, 1005 is not accumulated for the MVM.

Based on the accumulated charge, an analog-to-digital converter outputs a digital result. The controller then uses wordlines 1012 to turn off the select transistors 1008. One or more writeback cycles are used to read each mirror cell and then write the state read from the mirror cell to a corresponding memory cell 1002 or 1003. In this manner, the memory cells are restored to their original state existing prior to performing the MVM. In one example, the writeback can be performed by sensing a mirror cell and then performing the writeback using conventional writeback circuitry as in DRAM devices.

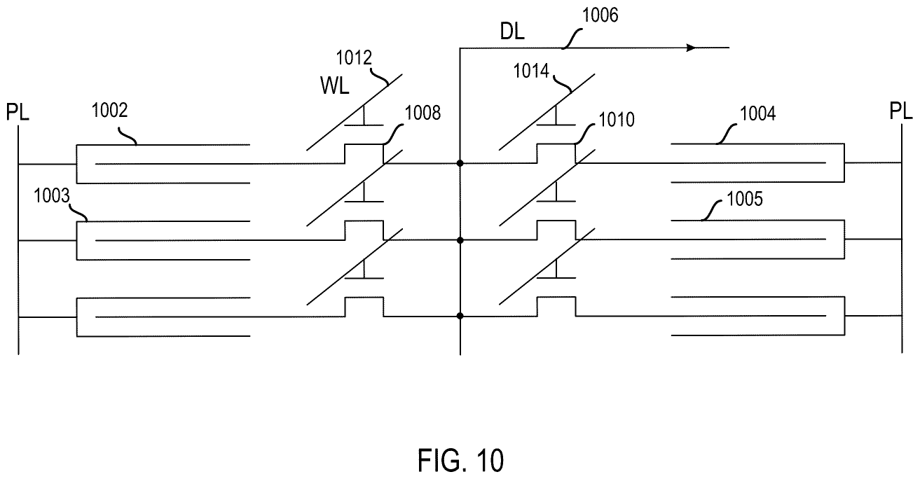

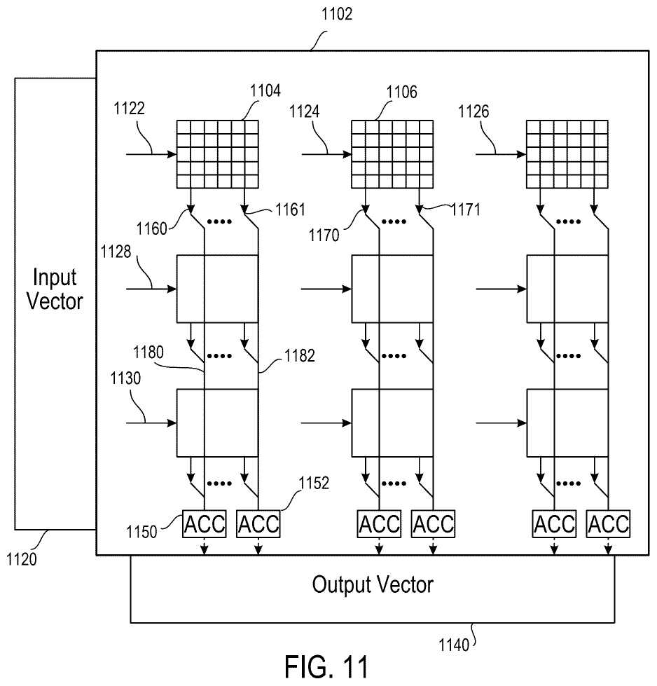

FIG. 11 shows tiles 1104, 1106 in a memory array 1102 used to store weights to perform multiplication of an input vector 1120 by the weights according to one embodiment. Memory array 1102 is an example of memory array 806.

Input vector 1120 is mapped to several wordlines within multiple tiles of array 1102. The output vector 1140 is generated by accumulation of partial sums from the tiles.

For example, portions of input vector 1120 can be mapped into tiles left to right (e.g., portions 1122, 1124, 1126) and/or top to bottom (e.g., portions 1122, 1120, 1130), as illustrated. In one example, each mapped portion is different. In one example, each mapped portion is a replication of the same input bits for performing parallel processing of the input in multiple tiles at the same time.

Each tile has sensing circuits used to accumulate charge and provide a digital result. For example, tile 1104 has sensing circuits 1160, 1161. Tile 1106 has sensing circuits 1170, 1171. Each sensing circuit (e.g., an analog-to-digital converter) provides a digital result. The digital results are summed across multiple tiles using lines (e.g., 1180, 1182), which are provided as inputs to accumulation circuitry (e.g., 1150, 1152). Accumulation circuitry (e.g., 1150, 1152) uses the sums across all tiles involved in the MVM to provide output vector 1140.

In one embodiment, the accumulation circuitry aggregates the partial sums of low-resolution ADCs of each tile into higher resolution results provided as output vector 1140.

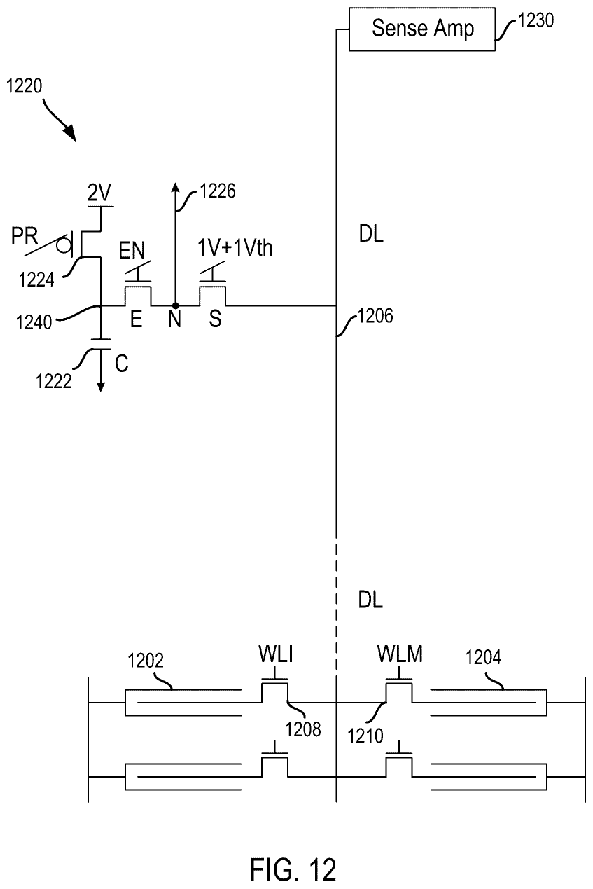

FIG. 12 shows sensing circuitry for determining a state of one or more memory cells according to one embodiment. In one example, the state is a magnitude of charge stored by one or more memory cells 1202. The sensing circuitry includes analog-to-digital converter (ADC) 1220 and sense amplifier 1230. The sensing circuitry is an example of sensing circuitry 150. Sense amplifier 1230 is an example of sense amplifiers 808.

ADC 1220 determines a magnitude of charge accumulated by sensing line 1206 (e.g., a digit line DL). Capacitor 1222 is pre-charged using transistor 1224 in preparation for this determination using pre-charge signal PR. Select transistor(s) 1208 are turned on by applying signal WLI using a wordline. Charge from memory cells 1202 is accumulated by sensing line 1206.

Sensing is enabled by turning on transistor E using signal EN. Signal 1226 from node N is provided to logic circuitry (not shown) used to determine the magnitude of the accumulated charge. Signal 1226 is modulated based on charge transfer from node N to sensing line 1206. Transistor S acts as a sense device biased to stop the flow of charge into the DL line based on the difference in voltage between node N and DL.

In one example, a counter of the logic circuitry is incremented during sensing. When a voltage of node N reaches a threshold, the counter is stopped. The value of the counter is used to determine the magnitude of the accumulated charge. In one example, the counter value is used to provide a digital result from the analog charge accumulation.

After sensing is complete, select transistor(s) 1208 are switched off. Select transistor(s) 1210 are switched on by applying signal WLM using one or more wordlines. The state of memory cells 1204, which act as mirror cells, is read. In one example, the state of the mirror cells is read by a sense amplifier 1230. The read state is used to recharge memory cells 1202 that were discharged during charge accumulation. The memory cells 1202 and mirror cells 1204 are recharged in one or more writeback (WB) cycles.

In one embodiment, the functionality of sense amplifier 1230 and/or writeback circuitry can be shared with functionality of ADC 1220.

In one example, the digit line DL has been discharged by some amount due to the cells selected on the DL. This charge will be replenished by small pulses of charge in a sequential manner from pre-charged capacitor 1222.

The transistor S acts as a sense device whose gate level modulates the point at which it becomes cut-off. This gate level is chosen to enable conduction up to the target voltage on the DL. When it is in the conduction range, the transistor S will allow the charge from capacitor 1222 through transistor E to flow to the DL. When transistor S reaches cut-off, the drain of the device will increase and will block charge from flowing into the DL. The point at which the node N increases in voltage will be detected and provided as signal 1226. This detection instructs a counter to stop counting (e.g., to stop counting clock cycles). The counter value represents the converted digital result from the charge accumulation.

In one example, a series of pulses is required to achieve the conversion. The conversion may be non-linear due to charge sharing effects, but the response can be linearized if desired.

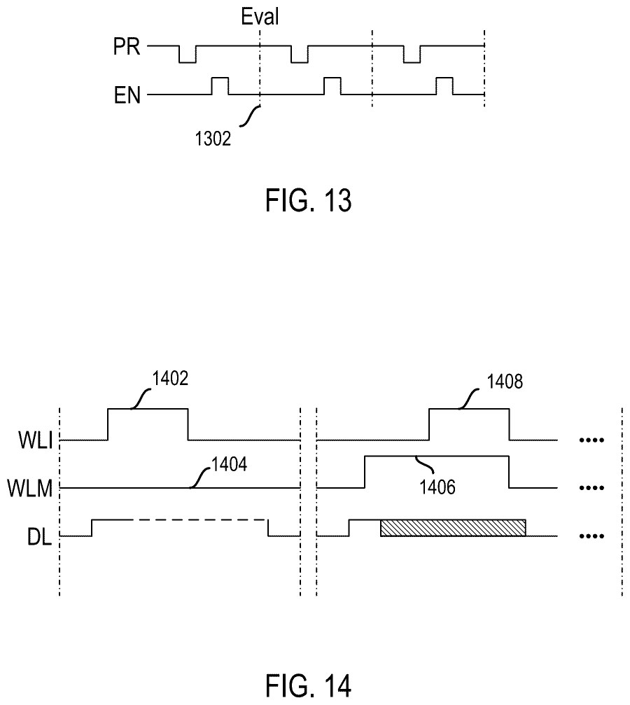

FIG. 13 shows exemplary voltage waveforms for inputs to the sensing circuitry of FIG. 12. Waveforms for signals PR and EN above are illustrated.

In one embodiment, charge accumulation occurs in three phases. Phase1: The PR signal (gate) is brought low to enable the PR transistor to pre-charge the capacitor to the pre-charge voltage (e.g., 2v, node 1240).

Phase2: the EN signal (gate) is brought high to pass the charge from node 1240 to the combined node N and node DL. In a first Case1: node DL is discharged relative to node 1240. The gate bias on transistor S allows the charge from node 1240 to pass onto node DL. Node N will also discharge.

In a second Case2: node DL is charged relative to node 1240. The gate bias on transistor S will block the charge from flowing to node DL. Node N will remain charged at the pre-charge level.

Phase3: node N is evaluated at time 1302. If case1 is true, node N will be low relative to the pre-charge voltage. If case2 is true, node N will remain close to the pre-charge voltage.

The Phases 1, 2, 3 are repeated. Each instance of case1 increments a counter. The counter stops when case2 is detected. The count represents a conversion of the total accumulated charge removed from the DL node (sensing line 1206) by cells 1202 connected to the DL node during MVM calculation.

FIG. 14 shows exemplary voltage waveforms for wordlines and a digit line in a memory array having memory cells being sensed using the sensing circuitry of FIG. 12. During charge accumulation, signal WLI is switched high at 1402 to turn on select transistors 1208. Signal WLM remains low at 1404 during accumulation to prevent access to the mirror cells.

During read and writeback, signal WLM is switched high at 1406 for reading and restoring the mirror cells. Signal WLI is switched high at 1408 for writeback to restore the original state of the memory cells used during charge accumulation.

In one embodiment, each memory cell can be viewed as providing a container that stores charge. The signal separation for MVM is typically not as critical as in memory applications. Thus, typically more noise and errors can be tolerated during the sum of products calculation.

As a result, conventional overall DRAM operation can be adjusted for MVM processing. For example, smaller DL loading, and smaller tiles can be used to support faster writes and reads. Smaller stored charge can be used to support lower energy dissipation per operation.

A smaller stored charge allows greater memory density. In one example, equivalently, for a dedicated silicon implementation, the container size may be reduced to improve on memory density. This can reduce the layout area impact due to use of mirror cells. In some cases, the refresh frequency may be reduced by accepting some signal loss.

As regards refresh and writeback, the refresh rate may be reduced since the state separation for MVM application is not as critical as for standard memory devices. In one embodiment, the writeback mechanism can be the same as in standard DRAM with support for multiple writeback cycles with potentially reduced writeback time in line with the relaxed state separation for MVM.

In one embodiment regarding writeback, the sense circuit reads the content of the mirror cell and writes its value back to the target cell and mirror cell at the same time. The mirror and target cells may or may not be next to each other. In some cases, parallel writeback is improved by having the memory cells on the same digit lines as the target cells.

In one embodiment regarding ADC and sensing, low resolution charge-based ADC can be used either as part of the sensing circuit or in addition to the sensing circuit. The ADC resolution and range may vary to support the partial accumulation of the target number of cells selected in parallel within a tile during MVM.

The pulsing sequence for WL and BL as well as biasing levels within the array can be selected to enhance the accumulated signal versus the background noise and capacitance. Further accumulation and aggregation of the partial sums can be supported in the digital domain to generate the required combined resolution (e.g., final result from MVM). In one example, these circuits may be present on the same silicon or on a bonded CMOS device.

In one example, the pre-charge capacitor 1222 of the ADC 1220 represents the capability or the sensitivity of the sensing circuit. The value of the capacitor can be adjusted depending on whether one cell is being sensed or multiple cells (e.g., 8-1,000 cells in parallel) are being sensed. The sensitivity of the sensing circuit can be adjusted depending on how many cells from which charge is being accumulated. A controller can select the capacitance of the pre-charge capacitor (e.g., by selecting sensing circuitry from among multiple different sensing circuitry options on a chip) depending on the number of cells to be sensed.

In one example, further accumulation and aggregation of partial sums is done. The output of each sense amp or ADC will be a digital value (e.g., a value having one bit or four bits). This digital value is sent to another circuit that will accumulate the digital values from multiple sense amps or ADCs.

FIG. 15 shows an input stream for multiplication by weights stored in a memory array 1502 where the input stream is provided to the memory array in sequential time slices according to one embodiment. Memory array 1502 is an example of memory cell array 113 or memory array 806.

Input patterns 1520, 1522 are provided to various wordlines of memory array 1502. Sets 1504 of memory cells (e.g., four cells as illustrated) store weights for use in multiplications. Charge is accumulated for the multiplication on digit lines 1530, 1532. Logic circuitry 1506, 1508 takes digital results from this charge accumulation and performs further processing to sum partial products from the digit lines 1530, 1532.

The input patterns 1520, 1522 can be provided as a series of bits in time slices. For example, a first bit of each pattern is provided in first time slice 1540. A second bit of each pattern is provided and second time slice 1542.

In one embodiment, the time slices are provided as truncated slices. In this approach, the duration of each time slice may be selected to correspond to the significance of the bit. For example, the duration of the first time slice (e.g., LSB) may be 5 ns, and the duration of the second time slice may be 10 ns due to its having a greater bit significance.

In one example, set 1504 contains four memory cells to represent one weight. Each memory cell stores one bit per cell, and the weight has a four-bit resolution.

In one example, the input streams have an eight-bit resolution. For example, input pattern 1520 has eight bits provided sequentially in time slices.

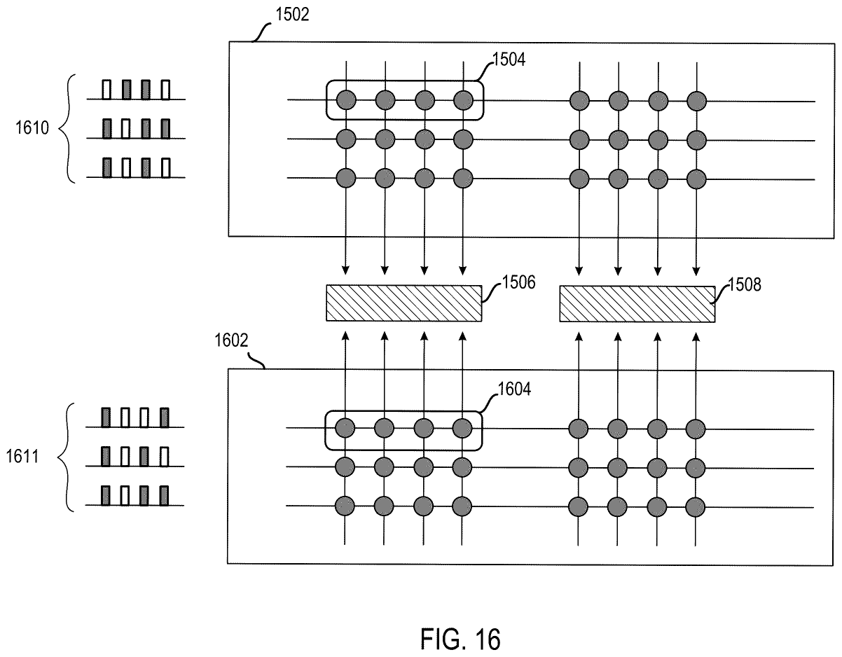

FIG. 16 shows replicating of weights stored in a memory array so that an input stream can be split into two parallel bit streams according to one embodiment. For example, weights stored as sets 1504 in memory array 1502 can be replicated to memory array 1602 and stored as identical weights 1604. This permits taking an input pattern having eight bits and processing the input pattern as two parallel input streams 1610, 1611 each having four bits. Input streams 1610, 1611 are provided sequentially as time slices. Computations to provide a final result from accumulated charge for various digit lines is done by logic circuitry 1506, 1508.

For example, an input pattern having eight bits can be split into a first input stream 1610 having the first four bits of the input pattern, and a second parallel input stream 1611 having the second four bits of the input pattern.

In one embodiment, a controller determines and selects a number of memory arrays to use for replicating weights to be used for a multiplication.

In one example regarding inputs and mapping to memory arrays, input patterns may be applied to the array as a stream of digital pulses in a time-sliced approach, where accumulation and conversion are carried out by slice. Smaller latency may be obtained by parallelizing these streams into multiple streams applied to different arrays (e.g., 1502, 1602) with replicated weight patterns (e.g., 1504, 1604).

In one example regarding sets of ADCs required for computation, there is a trade-off between memory density and power consumption. In one example, the use of lower resolution ADCs can reduce the accumulation time and the writeback time.

By extension to a simplest case, a single digital pulse may be applied into as many replicated arrays/tiles as for the input resolution desired. In this case the ADC becomes a single cell sense circuit.

For MVM operation, the timing and other parameters typically may be relaxed as compared to conventional DRAM memory in alignment with use of a reduced state separation of MVM. In some cases, this may result in better performance as compared to standard DRAM reads. Similarly, for dedicated silicon, simplifications in the process or architecture used may be made for MVM as compared to conventional memory such as use of smaller charge storage containers, faster sensing, etc.

In one example, to support multi-bit resolution of weights using one bit per cell (1 bpc), the weight cells can be arranged to share a common wordline. The different sensing lines (e.g., digit or bit lines) connecting the weight cells will be arranged by significance, and the partial sums will be handled appropriately in the digital domain (e.g., using logic circuitry 1506, 1508).

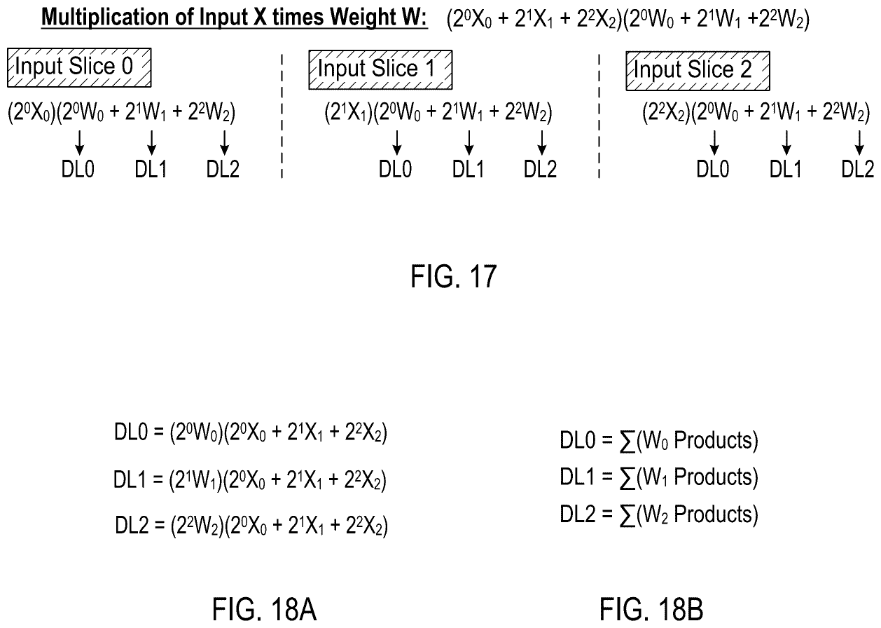

FIG. 17 shows an example of the calculation of partial products for the multiplication of an input by stored weights according to one embodiment. In the illustrated example, input X is multiplied times weight W. Input X is an example of input vector 1120. The weight is represented by memory cells each storing a partial weight W₀, W₁, W₂. Each weight is mapped to a digit line DL.

The input is provided in a series of time slices as described above. An individual bit-wise product appears on each digit line as a charge or current.

FIGS. 18A-18B show an example of the summation of partial products for each of multiple digit lines according to one embodiment. Results are combined across time slices on the same digit line. The slice results are weighted by the respective power of two associated with the respective portion of the input X. For example, when combining three digit lines into one result, each digit line DL is weighted by the respective power of two of the associated weights W.

This assignment carries to the summation of multiple products to provide sums for each of DL0, DL1, DL2. Each DL carries the sum of partial products across multiple time slices with the same power of two assignment.

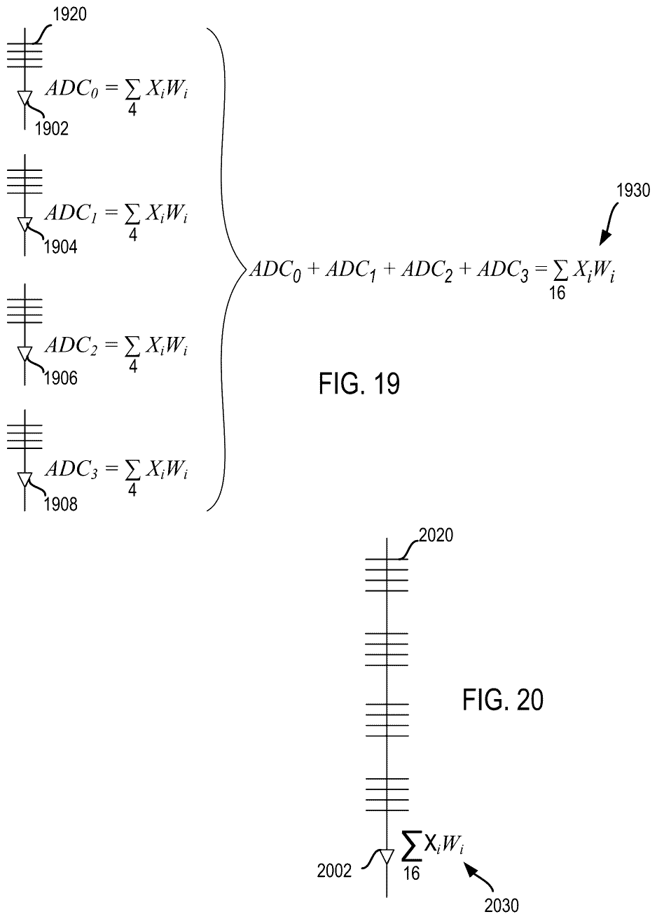

FIGS. 19-20 show summation of results from multiple low-resolution analog-to-digital converters (ADCs) 1902, 1904, 1906, 1908 to provide a final result 1930 that is equivalent to a high-resolution ADC 2002 according to one embodiment. In a specific example as illustrated, the output of each low-resolution ADC is based on accumulated charges from four memory cells selected using wordlines 1920.

High-resolution ADC 2002 provides an output based on accumulated charges from 16 memory cells selected using wordlines 2020. The accumulated charges are used to provide a final result 2030. In one embodiment, final result 1930 and final result 2030 are equivalent within a defined error tolerance. In one example, the sum of products from the low-resolution ADCs is equivalent to using the single high-resolution ADC 2002.

In one example, a DRAM array has 16 tiles. A low-resolution ADC for each tile provides a result. For example, four digit lines are used for charge accumulation per tile. A digital result is provided by the ADC from each tile. The final result is obtained by combining the digital results of all the tiles. This is equivalent to accumulating charge from all 16 tiles and providing the final result using a high-resolution ADC.

In one example for a sum of products operation, assuming no loss of signal in the conversion, summing the results of four ADCs of 2 bits resolution each is equivalent to having one ADC of 4 bits resolution. This is generalizable to other ADC resolutions. This can also be used in the reverse direction: given a desired final ADC resolution, a controller can determine the multiple of lower resolution ADCs to use for an MVM.

By selecting and using the multiple low-resolution ADCs as described above, one or more advantages can be achieved. For example, there are significant advantages in settling time, conversion time, parasitic IR drops, and/or conversion circuit complexity when operating with multiple lower resolution ADCs.

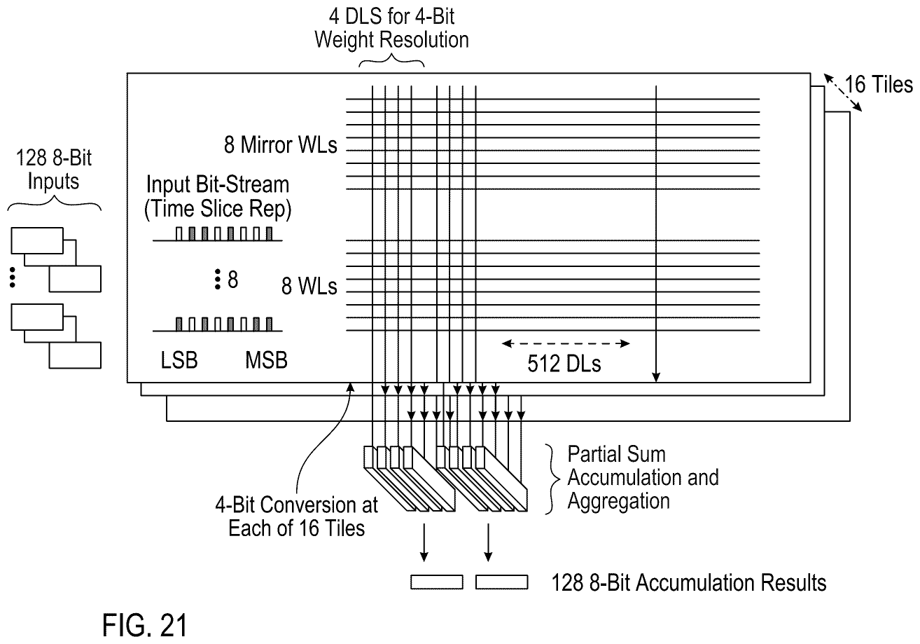

FIG. 21 shows an example of a logical tile in a DRAM device. The logical tile is distributed across multiple physical tiles (e.g., physical tiles in memory array(s) 806). Specifically, a 128 8bit-input×128 4bit-weight logical tile is distributed as illustrated across 16 physical tiles.

The input and output resolution are each 8 bits. Stored parameters have a 4 bit resolution using one bit per cell (1 bpc) storage. 8 word-lines per tile are selected in parallel on 16 tiles of 512 DLs per tile.

The input (e.g., input bit pattern 1520, 1522) is to be coded into 8 time-slices that are internally pulsed at an average, for example, 10 ns per slice. Accumulation and conversion are completed in the same average of 10 ns per time slice for a total of 80 ns using a truncated time slice (e.g., as described above) accumulation technique. Each time slice's accumulated output is shifted appropriately in the digital domain (e.g., using logic circuitry 1506, 1508) to account for the significance of the bits being converted during that time slice.

To obtain 8-bit accumulation across 16 tiles, 4 bit conversion is used at each tile: 2\hat{ }4 levels ADC resolution accumulated over 2\hat{ }4 instances.

The truncated accumulation technique allows for longer conversion time for more significant time slices relative to less significant slices with minimal error (e.g., slice times of 10,8,6,4,3,3,3,3 ns for an average=5 ns/slice). This enables faster effective accumulation.

Four memory cells are used at 1 bpc to encode 4 bits of weight resolution using 4 DLs. Thus, 4×128=512 DLs per tile are required. More DLs may be present in the physical tile, but it typically is more efficient to match this to the physical tile width.

Shorter MVM latency per tile can be supported by parallelizing the input pattern and mapping to additional tiles with replicated weights (e.g., as shown in FIG. 16). In one example, the slice time is split into two groups: 10,6,4 ns+8,3,3,3,3 ns. Each group's slice time is half as much as a single group. In some cases, the slice significance can be organized to optimize for this time.

The overall writeback overhead can be reduced by replicating tiles. For example, for 8 input slices, 64 writeback pulses are required. This is reduced in the above weight replication example to the larger of 3×8=24 pulses or 5×8=40 pulses.

In some embodiments, this replication may be optimized: if the second group contains lower resolution slices, the acceptable write back error may be relaxed for this group. This may also reduce the overall write back time.

In one example, the estimated writeback average cycle time is 10 ns determined as follows: 10 ns×8=80 ns per input slice to writeback array. Longer writeback times can be traded off against overall MVM latency or reduced density.

In one example, multiple such groups of 16 tiles can be enabled within one die. Assuming 16K tiles per die, 1K such MVM computations can be supported in parallel in one die.

Additional wordlines WLs and bit lines BLs within a tile can be provided and made available for computing additional MVM calculations in a sequential manner using new sets of weights (parameters). In the case where there is not enough sensing circuitry available in a chip, but more memory is available, a controller can switch to another set of weights and reuse the same sensing circuitry to calculate the next MVM cycle.

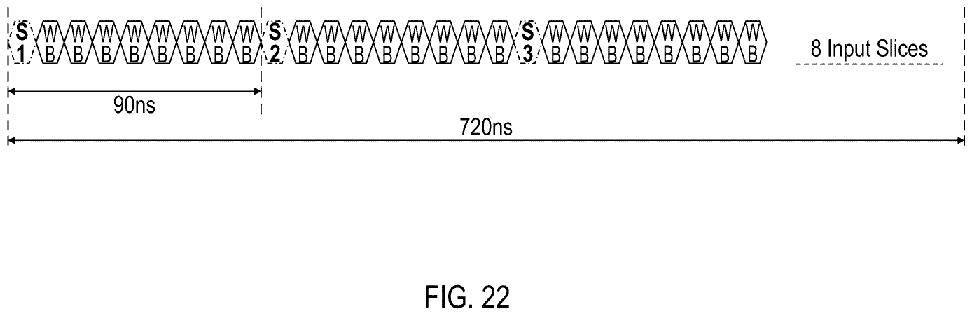

FIG. 22 shows exemplary timing for multiplications performed for the logical tile of FIG. 21 using an input stream provided in time slices with each time slice followed by multiple writeback cycles. In the illustrated example, the eight-bit input stream is processed as eight input time slices (S1, S2, S3, etc.). Each time slice is followed by eight writeback cycles (WB).

In one example, inference performance for a DRAM module of 128K tiles (16 GB module) can be determined as follows: 128K DRAM tiles activated equivalent to 128/16 128×128 composite MVM tiles (e.g., as illustrated in FIG. 21). 128×128×2*8K=256 MOps in 720 ns corresponding to 372 TOPS (Tera Operations per Second). Latency=720 ns.

In some embodiments, shorter latency can be traded off with TOPS performance by replication of weights as described above. Significant energy reduction is provided since parameters do not need to move back and forth to a GPU. For example, the density of the parameters in the logical tile at 4b resolution is 16 G parameters per 16 GB module (dynamic).

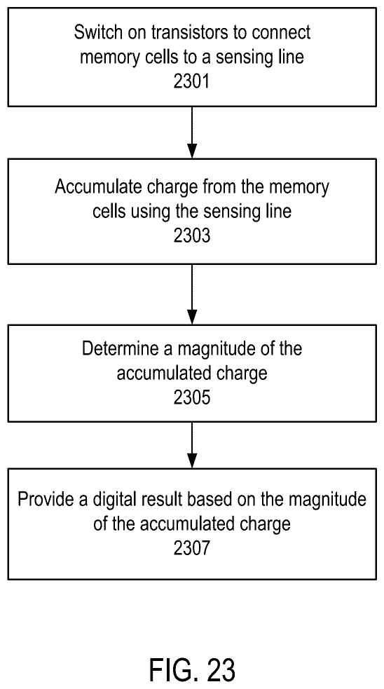

FIG. 23 shows a method for providing a digital result based on accumulating charge from multiple memory cells according to one embodiment. For example, the method of FIG. 23 can be implemented in the system of FIG. 1. In one example, controller 124 of FIG. 1 accumulates charge corresponding to weights stored in memory cells of memory cell array 113. In one example, the memory cells are programmed to store weights for a neural network. In one example, inputs from sensors 111 are multiplied by weights stored in the programmed memory cells.

The method of FIG. 23 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 23 is performed at least in part by one or more processing devices (e.g., controller 124, 804).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2301, transistors are switched on to connect memory cells to a sensing line. In one example, select transistors 1008 are switched on to connect memory cells 1002, 1003 to sensing line 1006.

At block 2303, charge is accumulated from the memory cells using the sensing line.

At block 2305, a magnitude of the accumulated charge is determined. In one example, analog-to-digital converter 1220 is used to determine the magnitude of the accumulated charge.

At block 2307, a digital result is provided based on the magnitude of the accumulated charge. In one example, ADC 1220 provides a digital result corresponding to the magnitude of the accumulated charge as determined using a counter.

In some aspects, the techniques described herein relate to an apparatus including: first memory cells (e.g., memory cells 1002, 1003 that store weights); second memory cells (e.g., mirror cells 1004, 1005 used to restore the state of memory cells 1002, 1003); and at least one controller configured to: accumulate charge stored in the first memory cells; and after accumulating the charge, restore the first memory cells based on charge stored in the second memory cells.

In some aspects, the techniques described herein relate to an apparatus, further including a sensing line (e.g., digit line 1006) connected to the first memory cells and the second memory cells, the sensing line configured to accumulate the charge from the first memory cells.

In some aspects, the techniques described herein relate to an apparatus, wherein restoring the first memory cells includes determining a state of the second memory cells and replicating the state to the first memory cells (e.g., reading and writing back the state of the mirror cells to the cells used in charge accumulation).

In some aspects, the techniques described herein relate to an apparatus, wherein the second memory cells are mirror cells, each mirror cell configured to mirror a state of a corresponding one of the first memory cells.

In some aspects, the techniques described herein relate to an apparatus, wherein the first memory cells are connected to a sensing line by first transistors (e.g., 1008), and the second memory cells are connected to the sensing line by second transistors (e.g., 1010).

In some aspects, the techniques described herein relate to an apparatus, wherein the charge is accumulated as part of performing a multiplication (e.g., MVM), the first transistors are turned on during the multiplication, and the second transistors are turned off during the multiplication.

In some aspects, the techniques described herein relate to an apparatus, wherein the first memory cells are restored after performing the multiplication, and restoring the first memory cells includes returning the first memory cells to a state existing prior to accumulating the charge.

In some aspects, the techniques described herein relate to an apparatus, wherein the second transistors are turned on to determine states of the second memory cells (e.g., read mirror cells), and the determined states are used to restore the first memory cells (e.g., perform writeback cycles based on reading the mirror cells).

In some aspects, the techniques described herein relate to an apparatus, wherein the controller is further configured to apply inputs for the multiplication to gates of the first transistors, and the inputs are applied serially in time slices (e.g., an MSB of a first input is applied in a first time slice, and an LSB of the first input is applied in a second time slice).

In some aspects, the techniques described herein relate to an apparatus, further including sensing circuitry configured to determine a state of each second memory cell, wherein the controller is further configured to replicate the state of each second memory cell to a corresponding one of the first memory cells.

In some aspects, the techniques described herein relate to an apparatus, wherein the controller is further configured to replicate the states of the second memory cells using a plurality of writeback cycles.

In some aspects, the techniques described herein relate to a method including: accumulating charge from a plurality of memory cells; and determining a magnitude of the accumulated charge by incrementing a counter (e.g., counting clock cycles when using ADC 1220).

In some aspects, the techniques described herein relate to a method, further including precharging a capacitor (e.g., 1222), wherein determining the magnitude includes incrementing the counter while discharging the capacitor.

In some aspects, the techniques described herein relate to a method, further including selecting a magnitude of capacitance for the capacitor based on a number of memory cells from which the charge will be accumulated.

In some aspects, the techniques described herein relate to a method, wherein: the charge is accumulated by a sensing line; the memory cells are connected to the sensing line by select transistors; a plurality of wordlines are connected to gates of the select transistors; and the method further includes switching on the select transistors by applying a voltage to the wordlines.

In some aspects, the techniques described herein relate to a method, further including providing a digital result based on a value of the counter.

In some aspects, the techniques described herein relate to a system including: a plurality of tiles, each tile including sensing circuitry; and at least one controller configured to: receive first weights from a host; and store the first weights by replicating the first weights into the tiles.

In some aspects, the techniques described herein relate to a system, wherein the tiles are configured in a dynamic random access memory array.

In some aspects, the techniques described herein relate to a system, wherein each tile stores a respective portion of the first weights, and the sensing circuitry is configured to measure accumulated charge from the tile when performing multiplication.

In some aspects, the techniques described herein relate to a system, wherein the sensing circuitry of each tile includes a analog-to-digital converter (ADC) configured to provide a respective result from a vector multiplication using those of the first weights stored in the respective tile.

In some aspects, the techniques described herein relate to a system, wherein the controller is further configured to sum a digital result from each tile to provide an output vector (e.g., 1140) corresponding to multiplication of an input vector (e.g., 1120) by the stored first weights.

Integrated circuit devices 101 (e.g., as in FIG. 1) can be configured as a storage device, a memory module, or a hybrid of a storage device and memory module. Examples of a storage device include a solid-state drive (SSD), a flash drive, a universal serial bus (USB) flash drive, an embedded multi-media controller (eMMC) drive, a universal flash storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The integrated circuit devices 101 (e.g., as in FIG. 1) can be installed in a computing system as a memory sub-system having an embedded image sensor and an inference computation capability. Such a computing system can be a computing device such as a desktop computer, a laptop computer, a network server, a mobile device, a portion of a vehicle (e.g., airplane, drone, train, automobile, or other conveyance), an internet of things (IoT) enabled device, an embedded computer (e.g., one included in a vehicle, industrial equipment, or a networked commercial device), or such a computing device that includes memory and a processing device.

In general, a computing system can include a host system that is coupled to one or more memory sub-systems (e.g., integrated circuit device 101 of FIG. 1). In one example, a host system is coupled to one memory sub-system.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

For example, the host system can include a processor chipset (e.g., processing device) and a software stack executed by the processor chipset. The processor chipset can include one or more cores, one or more caches, a memory controller (e.g., NVDIMM controller), and a storage protocol controller (e.g., PCIe controller, SATA controller). The host system uses the memory sub-system, for example, to write data to the memory sub-system and read data from the memory sub-system.

The host system can be coupled to the memory sub-system via a physical host interface. Examples of a physical host interface include, but are not limited to, a serial advanced technology attachment (SATA) interface, a peripheral component interconnect express (PCIe) interface, a universal serial bus (USB) interface, a fibre channel, a serial attached SCSI (SAS) interface, a double data rate (DDR) memory bus interface, a small computer system interface (SCSI), a dual in-line memory module (DIMM) interface (e.g., DIMM socket interface that supports double data rate (DDR)), an open NAND flash interface (ONFI), a double data rate (DDR) interface, a low power double data rate (LPDDR) interface, a compute express link (CXL) interface, or any other interface. The physical host interface can be used to transmit data between the host system and the memory sub-system. The host system can further utilize an NVM express (NVMe) interface to access components (e.g., memory devices) when the memory sub-system is coupled with the host system by the PCIe interface. The physical host interface can provide an interface for passing control, address, data, and other signals between the memory sub-system and the host system. In general, the host system can access multiple memory sub-systems via a same communication connection, multiple separate communication connections, or a combination of communication connections.

The processing device of the host system can be, for example, a microprocessor, a central processing unit (CPU), a processing core of a processor, an execution unit, etc. In some instances, the controller can be referred to as a memory controller, a memory management unit, or an initiator. In one example, the controller controls the communications over a bus coupled between the host system and the memory sub-system. In general, the controller can send commands or requests to the memory sub-system for desired access to memory devices. The controller can further include interface circuitry to communicate with the memory sub-system. The interface circuitry can convert responses received from the memory sub-system into information for the host system.

The controller of the host system can communicate with a controller of the memory sub-system to perform operations such as reading data, writing data, or erasing data at the memory devices, and other such operations. In some instances, the controller is integrated within the same package of the processing device. In other instances, the controller is separate from the package of the processing device. The controller or the processing device can include hardware such as one or more integrated circuits (ICs), discrete components, a buffer memory, or a cache memory, or a combination thereof. The controller or the processing device can be a microcontroller, special-purpose logic circuitry (e.g., a field programmable gate array (FPGA), an application specific integrated circuit (ASIC), etc.), or another suitable processor.

The memory devices can include any combination of the different types of non-volatile memory components and volatile memory components. The volatile memory devices can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, or a PLC portion of memory cells, or any combination thereof. The memory cells of the memory devices can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), spin transfer torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller (or controller for simplicity) can communicate with the memory devices to perform operations such as reading data, writing data, or erasing data at the memory devices and other such operations (e.g., in response to commands scheduled on a command bus by controller). The controller can include hardware such as one or more integrated circuits (ICs), discrete components, or a buffer memory, or a combination thereof. The hardware can include digital circuitry with dedicated (i.e., hard-coded) logic to perform the operations described herein. The controller can be a microcontroller, special-purpose logic circuitry (e.g., a field programmable gate array (FPGA), an application specific integrated circuit (ASIC), etc.), or another suitable processor.

The controller can include a processing device (processor) configured to execute instructions stored in a local memory. In the illustrated example, the local memory of the controller includes an embedded memory configured to store instructions for performing various processes, operations, logic flows, and routines that control operation of the memory sub-system, including handling communications between the memory sub-system and the host system.

In some embodiments, the local memory can include memory registers storing memory pointers, fetched data, etc. The local memory can also include read-only memory (ROM) for storing micro-code. While the example memory sub-system includes a controller, in another embodiment of the present disclosure, a memory sub-system does not include a controller, and can instead rely upon external control (e.g., provided by an external host, or by a processor or controller separate from the memory sub-system).

In general, the controller can receive commands or operations from the host system and can convert the commands or operations into instructions or appropriate commands to achieve the desired access to the memory devices. The controller can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices. The controller can further include host interface circuitry to communicate with the host system via the physical host interface. The host interface circuitry can convert the commands received from the host system into command instructions to access the memory devices as well as convert responses associated with the memory devices into information for the host system.

The memory sub-system can also include additional circuitry or components that are not illustrated. In some embodiments, the memory sub-system can include a cache or buffer (e.g., DRAM) and address circuitry (e.g., a row decoder and a column decoder) that can receive an address from the controller and decode the address to access the memory devices.

In some embodiments, the memory devices include local media controllers that operate in conjunction with memory sub-system controller to execute operations on one or more memory cells of the memory devices. An external controller (e.g., memory sub-system controller) can externally manage the memory device (e.g., perform media management operations on the memory device). In some embodiments, a memory device is a managed memory device, which is a raw memory device combined with a local media controller for media management within the same memory device package. An example of a managed memory device is a managed NAND (MNAND) device.

The controller or a memory device can include a storage manager configured to implement storage functions discussed above. In some embodiments, the controller in the memory sub-system includes at least a portion of the storage manager. In other embodiments, or in combination, the controller or the processing device in the host system includes at least a portion of the storage manager. For example, the controller, or the processing device can include logic circuitry implementing the storage manager. For example, the controller, or the processing device (processor) of the host system, can be configured to execute instructions stored in memory for performing the operations of the storage manager described herein. In some embodiments, the storage manager is implemented in an integrated circuit chip disposed in the memory sub-system. In other embodiments, the storage manager can be part of the firmware of the memory sub-system, an operating system of the host system, a device driver, or an application, or any combination therein.

In one embodiment, an example machine of a computer system within which a set of instructions, for causing the machine to perform any one or more of the methods discussed herein, can be executed. In some embodiments, the computer system can correspond to a host system that includes, is coupled to, or utilizes a memory sub-system or can be used to perform the operations described above. In alternative embodiments, the machine can be connected (e.g., networked) to other machines in a LAN, an intranet, an extranet, or the internet, or any combination thereof. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a personal digital assistant (PDA), a cellular telephone, a web appliance, a server, a network router, a switch or bridge, a network-attached storage facility, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system includes a processing device, a main memory (e.g., read-only memory (ROM), flash memory, dynamic random access memory (DRAM) such as synchronous DRAM (SDRAM) or Rambus DRAM (RDRAM), static random access memory (SRAM), etc.), and a data storage system, which communicate with each other via a bus (which can include multiple buses).

A processing device can be one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. A processing device can also be one or more special-purpose processing devices such as an application specific integrated circuit (ASIC), a field programmable gate array (FPGA), a digital signal processor (DSP), network processor, or the like. The processing device is configured to execute instructions for performing the operations and steps discussed herein. The computer system can further include a network interface device to communicate over the network.

The data storage system can include a machine-readable medium (also known as a computer-readable medium) on which is stored one or more sets of instructions or software embodying any one or more of the methodologies or functions described herein. The instructions can also reside, completely or at least partially, within the main memory and within the processing device during execution thereof by the computer system, the main memory and the processing device also constituting machine-readable storage media. The machine-readable medium, data storage system, or main memory can correspond to the memory sub-system.

In one embodiment, the instructions include instructions to implement functionality corresponding to the operations described above. While the machine-readable medium is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

In one embodiment, a memory device includes a controller that controls voltage drivers (e.g., 203, 213, 223 of FIG. 2) and/or other components of the memory device. The controller is instructed by firmware or other software. The software can be stored on a machine-readable medium as instructions, which can be used to program the controller. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations may be described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special-purpose circuitry, with or without software instructions, such as using application-specific integrated circuit (ASIC) or field-programmable gate array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. An apparatus comprising:
first memory cells;
second memory cells; and
at least one controller configured to:
accumulate charge stored in the first memory cells; and
after accumulating the charge, restore the first memory cells based on charge stored in the second memory cells.

2. The apparatus of claim 1, further comprising a sensing line connected to the first memory cells and the second memory cells, the sensing line configured to accumulate the charge from the first memory cells.

3. The apparatus of claim 1, wherein restoring the first memory cells comprises determining a state of the second memory cells and replicating the state to the first memory cells.

4. The apparatus of claim 1, wherein the second memory cells are mirror cells, each mirror cell configured to mirror a state of a corresponding one of the first memory cells.

5. The apparatus of claim 1, wherein the first memory cells are connected to a sensing line by first transistors, and the second memory cells are connected to the sensing line by second transistors.

6. The apparatus of claim 5, wherein the charge is accumulated as part of performing a multiplication, the first transistors are turned on during the multiplication, and the second transistors are turned off during the multiplication.

7. The apparatus of claim 6, wherein the first memory cells are restored after performing the multiplication, and restoring the first memory cells comprises returning the first memory cells to a state existing prior to accumulating the charge.

8. The apparatus of claim 6, wherein the second transistors are turned on to determine states of the second memory cells, and the determined states are used to restore the first memory cells.

9. The apparatus of claim 6, wherein the controller is further configured to apply inputs for the multiplication to gates of the first transistors, and the inputs are applied serially in time slices.

10. The apparatus of claim 1, further comprising sensing circuitry configured to determine a state of each second memory cell, wherein the controller is further configured to replicate the state of each second memory cell to a corresponding one of the first memory cells.

11. The apparatus of claim 10, wherein the controller is further configured to replicate the states of the second memory cells using a plurality of writeback cycles.

12. A method comprising:
accumulating charge from a plurality of memory cells; and
determining a magnitude of the accumulated charge by incrementing a counter.

13. The method of claim 12, further comprising precharging a capacitor, wherein determining the magnitude includes incrementing the counter while discharging the capacitor.

14. The method of claim 13, further comprising selecting a magnitude of capacitance for the capacitor based on a number of memory cells from which the charge will be accumulated.

15. The method of claim 12, wherein:
the charge is accumulated by a sensing line;
the memory cells are connected to the sensing line by select transistors;
a plurality of wordlines are connected to gates of the select transistors; and
the method further comprises switching on the select transistors by applying a voltage to the wordlines.

16. The method of claim 12, further comprising providing a digital result based on a value of the counter.

17. A system comprising:
a plurality of tiles, each tile comprising sensing circuitry; and
at least one controller configured to:
receive first weights from a host; and
store the first weights by replicating the first weights into the tiles.

18. The system of claim 17, wherein the tiles are configured in a dynamic random access memory array.

19. The system of claim 17, wherein each tile stores a respective portion of the first weights, and the sensing circuitry is configured to measure accumulated charge from the tile when performing multiplication.

20. The system of claim 17, wherein the sensing circuitry of each tile comprises a analog-to-digital converter (ADC) configured to provide a respective result from a multiplication using those of the first weights stored in the respective tile.

21. The system of claim 17, wherein the controller is further configured to sum a digital result from each tile to provide an output vector corresponding to multiplication of an input vector by the stored first weights.
